(19) United States
(12) Patent Application Publication
(10) Pub. No.: US 2026/0312630 A1
(43) Pub. Date: Oct. 8, 2026

(54) SYSTEM AND METHOD FOR MITIGATING INTERFERENCE OF A WIRELESS SIGNAL RECEIVED AND REFLECTED AT A RECONFIGURABLE METASURFACE UNIT CELL ARRAY USING A CONDITIONAL GENERATIVE ADVERSARIAL NETWORK ALGORITHM

(71) Applicant: Dell Products LP, Round Rock, TX (US)

(72) Inventors: Tejinder Singh, Manotick (CA); Navjot Kaur Khaira, Manotick (CA); Harpreet S. Narula, Austin, TX (US)

(73) Assignee: Dell Products LP, Round Rock, TX (US)

(21) Appl. No.: 19/172,063

(22) Filed: Apr. 7, 2025

(51) Int. Cl. H04B 7/04

(52) U.S. Cl. CPC H04B 7/04013; G06F 30/34; H01Q 15/0026

(57) ABSTRACT

A system and method of mitigating radiofrequency signal interference at a reconfigurable metasurface unit cell array comprising a plurality of reconfigurable unit cells to reflect a reflected radiofrequency signal in a radiofrequency environment comprising the plurality of metasurface unit cells. Capturing, via a partial signal coupler, a portion of an incident radiofrequency signal as a captured incident radiofrequency signal. The centralized metasurface hardware controller executes machine readable code instructions of a signal feature extraction and preprocessing module to identify feature characteristics data, including identifying a wireless communication component and interference components, of the captured incident radiofrequency signal provided as input to a conditional generative adversarial network algorithm to generate, as output, a filtered offset radiofrequency signal. The filtered offset radiofrequency signal has attenuation and phase change applied across the metasurface unit cells and is combined with the incident radiofrequency signal into the reflected radiofrequency signal having a suppressed interference component.

### FIELD OF THE DISCLOSURE

The present disclosure generally relates to a system and method of adaptively enhancing wireless communication systems in a radiofrequency environment. More specifically, the present disclosure relates to a system and method of mitigating interference of a wireless signal received and reflected at a reconfigurable metasurface unit cell array using a conditional generative adversarial network (cGAN) algorithm for filtering and phase shift adjustments.

### BACKGROUND

As the value and use of information continues to increase, individuals and businesses seek additional ways to process and store information. One option available to clients is information handling systems. An information handling system generally processes, compiles, stores, and/or communicates information or data for business, personal, or other purposes thereby allowing clients to take advantage of the value of the information. Because technology and information handling may vary between different clients or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific client or specific use, such as e-commerce, financial transaction processing, airline reservations, enterprise data storage, or global communications. In addition, information handling systems may include a variety of hardware and software components that may be configured to process, store, and communicate information and may include one or more computer systems, data storage systems, and networking systems. The information handling system may include telecommunication, network communication, and video communication capabilities. The information handling system may be used with a wireless interface adapter to transmit and receive wireless communications with other wireless devices in a radiofrequency environment that may include a reconfigurable metasurface to reflect radiofrequency signals.

### BRIEF DESCRIPTION OF THE DRAWINGS

It will be appreciated that for simplicity and clarity of illustration, elements illustrated in the Figures are not necessarily drawn to scale. For example, the dimensions of some elements may be exaggerated relative to other elements. Embodiments incorporating teachings of the present disclosure are shown and described with respect to the drawings herein, in which:

FIG. 1 is a block diagram illustrating an information handling system and a reconfigurable metasurface unit cell array operatively controlled by a centralized metasurface hardware controller and metasurface embedded microcontrollers for subgroups of metasurface unit cells to mitigate radiofrequency interference within a radiofrequency environment according to an embodiment of the present disclosure;

FIG. 2 is a block diagram illustrating a plurality of information handling systems and a metasurface unit cell array in a radiofrequency environment operatively controlled by a centralized metasurface hardware controller and metasurface embedded microcontrollers for subgroups of metasurface unit cells to mitigate radiofrequency interference in reflected radiofrequency signals according to another embodiment of the present disclosure;

FIG. 3 is an exploded perspective view graphic diagram showing one of a plurality of metasurface unit cell subgroups of metasurface unit cells of a reconfigurable metasurface unit cell array operatively coupled to a centralized metasurface hardware controller and a metasurface embedded microcontroller according to an embodiment of the present disclosure;

FIG. 4 is an exploded perspective view graphic diagram showing a reconfigurable metasurface unit cell array with a plurality of metasurface unit cells grouped into metasurface unit cell subgroups operatively coupled to metasurface embedded microcontrollers and a centralized metasurface controller according to an embodiment of the present disclosure;

FIG. 5 is a top view graphic diagram showing an exploded view of one of a plurality of metasurface unit cell subgroups forming as a portion of a reconfigurable metasurface unit cell array used to detect angle-of-arrival (AoA) of incident radiofrequency signals and determine an appropriate angle-of-departure (AoD) for reflected radiofrequency signals in a radiofrequency environment according to an embodiment of the present disclosure;

FIG. 6 is a swim lane flow diagram showing a method of mitigating radiofrequency signal interference at a reconfigurable metasurface unit cell array under control of a centralized metasurface hardware controller executing a cGAN algorithm according to an embodiment of the present disclosure; and

FIG. 7 is a flow diagram of a method of mitigating radiofrequency signal interference at a reconfigurable metasurface unit cell array under control of a centralized metasurface hardware controller executing a cGAN algorithm according to an embodiment of the present disclosure according to another embodiment of the present disclosure.

The use of the same reference symbols in different drawings may indicate similar or identical items.

### DETAILED DESCRIPTION OF THE DRAWINGS

The following description in combination with the Figures is provided to assist in understanding the teachings disclosed herein. The description is focused on specific implementations and embodiments of the teachings and is provided to assist in describing the teachings. This focus should not be interpreted as a limitation on the scope or applicability of the teachings.

Wireless data transmission from a transmitting device to a receiving device in a radiofrequency environment allows for rapid data transmission and communication between multiple devices. Wireless transmitting and receiving devices may include wirelessly enabled information handling systems, access point devices, or any computing device, such as internet of things (IoT) devices that are wirelessly capable. As data transmission requirements increase, the electromagnetic (EM) wave (e.g., 5G technologies using 20 to 50 GHz wireless signals or other frequencies, or WiFi 6 signals at 2.4 GHz, 5 GHz or even 6 GHz) used to transmit these ever-increasing amounts of data are shortened or may benefit from extended range such as reach around radiofrequency barriers such as walls. With reconfigurable intelligent surfaces, also known as reconfigurable metasurfaces, these higher frequencies may be relayed around objects such as walls in order to extend the range of these relatively higher transmission wavelengths by reflecting the wireless transmissions of wireless network communications off of their surfaces. However, these wireless networks can get highly congested with multiple network devices competing for channel allocation and bandwidth within the wireless network operating in a radiofrequency environment. This may create significant interference in the wireless transmission radiofrequency signals.

The present specification describes a system and method of mitigating radiofrequency signal interference in a radiofrequency environment at a reconfigurable metasurface unit cell array. In an embodiment, the reconfigurable metasurface unit cell array may include centralized metasurface processing including a centralized metasurface hardware controller with metasurface neural processing unit (NPU) capabilities, and a metasurface memory device. The reconfigurable metasurface unit cell array may include a metasurface power management unit (PMU) to provide power to the centralized metasurface hardware controller with metasurface neural processing unit (NPU) capabilities, and the metasurface memory device. Further, the metasurface PMU may provide power to embedded metasurface microcontrollers and tunable delay circuits, tunable varactors, tunable attenuator circuits and the like for control of individual subgroups of metasurface unit cells within the wider reconfigurable metasurface unit cell array. In an embodiment, the reconfigurable metasurface unit cell array may be used to manipulate radiofrequency signals incident to the surface of the reconfigurable metasurface unit cell array received within a radiofrequency environment. The reconfigurable metasurface unit cell array may include a plurality of metasurface unit cells formed into metasurface unit cell subgroups each with control by a designated embedded microcontroller unit.

During operation, in an embodiment, the embedded metasurface microcontroller may receive the incident radiofrequency signals from each of the plurality of metasurface unit cells via a partial signal coupler and microwave coupler circuit at each of the metasurface unit cells and pass this captured radiofrequency, including interference, to a centralized metasurface hardware controller. The centralized metasurface hardware controller may then execute machine readable code instructions of a signal feature extraction and preprocessing module to identify characteristics of the incident radiofrequency signals. In an embodiment, a hardware metasurface neural processing unit (NPU) as part of or as a separate hardware resource with the centralized metasurface hardware controller may then execute machine readable code instructions of a conditional generative adversarial network (cGAN) algorithm that receives, as input, the characteristics of the incident radiofrequency signals, the captured incident radiofrequency signals, and a generated random noise signal from a noise generator to provide, as output, a filtered offset radiofrequency signal. This filtered offset radiofrequency signal, in an embodiment, may be transmitted to the metasurface embedded microcontrollers from which the captured, incident radiofrequency signals were received by the metasurface hardware controller for a plurality of metasurface embedded microcontrollers to apply an appropriate attenuation and phase change and retransmit the filtered offset radiofrequency signal as reflected radiofrequency signals reflected off of the surface of the reconfigurable metasurface unit cell array with reduced interference. In an embodiment, the attenuation and phase change applied to the filtered offset radiofrequency signal may be accomplished by the metasurface embedded microcontrollers accessing an attenuation circuit and a tunable delay circuit for each subgroup of metasurface unit cells to generate constructive or destructive interference as appropriate to enhance gain of the reflected radiofrequency signal or to reduce the interference portion of the incident radiofrequency signal.

In an embodiment, the characteristics of the incident radiofrequency signals may also include angle-of-arrival (AoA) data, angle-of-departure (AoD) data, and time-of-flight (ToF) data that may also be used as input to the cGAN and a dynamic reinforcement learning (DRL) algorithm. This may further train the cGAN and DRL to provide, as output, the filtered offset radiofrequency signal for attenuation and phase change for managing plural metasurface embedded microcontrollers to apply an appropriate attenuation and phase change and retransmit the filtered offset radiofrequency signal as reflected radiofrequency signals across plural subgroups of metasurface unit cells in the reconfigurable metasurface unit cell array. In an embodiment, the central metasurface hardware controller may calculate the AoA data by detecting a difference in the arrival time of the incident radiofrequency signals at each of the metasurface unit cells with known dimension and spacing within the metasurface unit cell subgroups of the reconfigurable metasurface unit cell array. The AoD data may also be calculated by extrapolating the direction of the incoming incident radiofrequency signals based on the AoA thereby determining the direction of the transmitting network device. Still further, the ToF data may be determined by direct time delay measurements (e.g., embedded signal in incident radiofrequency signals compared to elapsed time), or frequency domain analysis (e.g., Fourier transform and wavelet-based estimation) among other techniques to determine the ToF data.

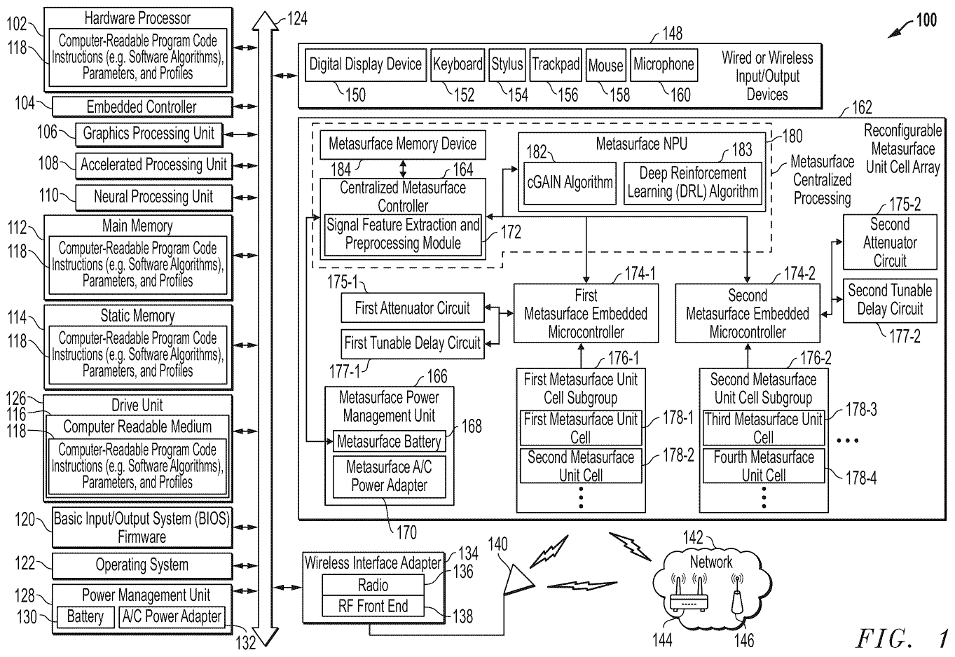

Turning now to the figures, FIG. 1 illustrates an information handling system 100 similar to the information handling systems according to several aspects of the present disclosure that may operate as a source or target radiofrequency device for wirelessly interfacing with a reconfigurable metasurface unit cell array of the embodiments of the present disclosure. It is appreciated that terms such as “metasurface unit cell array” or “reconfigurable metasurface unit cell array” are meant to be understood as a metasurface that includes a plurality of metasurface unit cells formed as tiles or surfaces that, with control via a microwave circuit and hardware processing resources such as a hardware controller or embedded microcontrollers, operate together to engage in, at least, reflecting, beamforming, and transmission of reflected radiofrequency signals in a radiofrequency environment. In the embodiments described herein, an information handling system 100 includes any instrumentality or aggregate of instrumentalities operable to compute, classify, process, transmit, receive, retrieve, originate, switch, store, display, manifest, detect, record, reproduce, handle, or use any form of information, intelligence, or data for business, scientific, control, entertainment, or other purposes. For example, an information handling system 100 may be a personal computer, mobile device (e.g., personal digital assistant (PDA) or smart phone), server (e.g., blade server or rack server), a consumer electronic device, a network server or storage device, a network router, switch, or bridge, wireless router, or other network communication device, a network connected device (cellular telephone, tablet device, etc.), IoT computing device, wearable computing device, a set-top box (STB), a mobile information handling system, a palmtop computer, a laptop computer, a desktop computer, a communications device, an access point (AP) 144, a base station transceiver 146, a wireless telephone, a control system, a camera, a scanner, a printer, a personal trusted device, a web appliance, or any other suitable machine capable of executing a set of instructions (sequential or otherwise) that specify actions to be taken by that machine, and may vary in size, shape, performance, price, and functionality.

In a networked deployment, the information handling system 100 may operate in the capacity of a client computer in a server-client network environment, or as a peer computer system within a peer-to-peer (or distributed) network environment. In an embodiment, the information handling system 100 may be implemented using electronic devices that provide voice, video, or data communication. For example, an information handling system 100 may be any mobile or other computing device capable of executing a set of instructions (sequential or otherwise) that specify actions to be taken by that machine. Further, while a single information handling system 100 is illustrated, the term “system” shall also be taken to include any collection of systems or sub-systems that individually or jointly execute a set, or plural sets, of instructions to perform one or more computer functions.

The information handling system 100 may include main memory 112, (volatile (e.g., random-access memory, etc.), or static memory 114, nonvolatile (read-only memory, flash memory etc.) or any combination thereof), one or more hardware processing resources, such as a hardware processor 102 that may be a central processing unit (CPU), embedded controller (EC) 104, a graphics processing unit (GPU) 106, a neural processing unit (NPU) 110, an accelerated processing unit (APU) 108, other types of hardware processing devices, or any combination thereof. It is appreciated that the information handling system 100 may include any number of hardware processing devices described herein. Computer readable code instructions stored in main memory 112 (e.g., RAM) may be accessible by hardware processing resources using that main memory 112. Machine readable code instructions stored in static memory 114, main memory 112, or drive unit 126 may be involved in invoking such machine readable code instructions to main memory 112 according to embodiments herein. Additional components of the information handling system 100 may include one or more storage devices such as static memory 114 or drive unit 126. The information handling system 100 may include or interface with one or more communications ports for communicating with external devices, as well as various wired or wireless input and output (I/O) devices 148, such as a mouse 158, a trackpad 156, a stylus 154, a keyboard 152, a digital display device 150, a microphone 160, or any combination thereof. Portions of an information handling system 100 may themselves be considered information handling systems 100.

Information handling system 100 may include devices or modules that embody one or more of the devices or execute instructions for one or more systems and modules. The information handling system 100 may execute machine readable code instructions (e.g., software algorithms) parameters, and profiles 118 that may operate on servers or systems, remote data centers, or on-box in individual client information handling systems according to various embodiments herein. In some embodiments, it is understood any or all portions of machine readable code instructions (e.g., software algorithms) parameters, and profiles 118 may operate on a plurality of information handling systems 100.

The information handling system 100 may include the hardware processor 102 such as a central processing unit (CPU) or other hardware processing resource (e.g., 104, 106, 108, 110). Any of the hardware processing resources may operate to execute computer readable code instructions that are either firmware or software code, such as those software systems and modules described herein. Moreover, the information handling system 100 may include memory such as main memory 112, static memory 114, and disk drive unit 126 (volatile (e.g., random-access memory, etc.), nonvolatile memory (read-only memory, flash memory etc.) or any combination thereof or other memory with computer readable medium 116 storing machine readable code instructions (e.g., software algorithms) parameters, and profiles 118 executable by the hardware processor 102 (e.g., central processing unit), NPU 110, APU 108, EC 104, GPU 106, or any other hardware processing device. The information handling system 100 may also include one or more buses 124 operable to transmit communications between the various hardware components such as any combination of various wired or wireless I/O devices 148 as well as between hardware processors 102, an EC 104, the operating system (OS) 122, the basic input/output system (BIOS) 120, the wireless interface adapter 134, or a radio module, among other components described herein. In an embodiment, the hardware processor 102, EC 104, GPU 106, NPU 110, APU 108, and/or others may execute one or more bus drivers in order to transmit this data between the information handling system 100 and the wired or wireless input/output devices 148 described herein. In an embodiment, the information handling system 100 may be in wired or wireless communication with the wired or wireless I/O devices 148 such as a keyboard 152, a mouse 158, digital display device 150, stylus 154, trackpad 156, microphone 160, among other peripheral devices.

As described herein, the information handling system 100 further includes a digital display device 150. The digital display device 150 in an embodiment may function as a liquid crystal display (LCD), an organic light emitting diode (OLED), a flat panel display, or a solid-state display. It is appreciated that the digital display device 150 may be wired or wireless and may be an external digital display device 150 that allows a user to increase the desktop area by extending the desktop in an embodiment. Additionally, as described herein, the information handling system 100 may include or be operatively coupled to a cursor control device (e.g., a trackpad 156, or gesture or touch screen input), a stylus 154, and/or a keyboard 152, among others that allows the user to interface with the information handling system 100 via the digital display device 150. Information handling system 100 may also be operatively coupled to a wired or wireless input/output device 148 or other hardware devices that may include a hardware processing device such as a hardware processor, microcontroller, or other hardware processing resource. Various drivers and hardware control device electronics may be operatively coupled to operate the wired or wireless I/O devices 148 according to the embodiments described herein. The present specification contemplates that the wired or wireless I/O devices 148 may be wired or wireless.

A network interface device of the information handling system 100 may be wired or wireless such as shown with wireless interface adapter 134 that can provide wireless connectivity among plural devices in a radiofrequency environment such as with Bluetooth® or to a network 142 such as with a wide area network (WAN), a local area network (LAN), wireless local area network (WLAN), a wireless personal area network (WPAN), a wireless wide area network (WWAN), or other network. In embodiments described herein, the wireless interface device 134 with its radio 136, RF front end 138 and one or more antennas 140 is used to communicate with the wireless peripheral devices, via, for example, a Bluetooth® or Bluetooth® Low Energy (BLE) protocols or any proprietary RF protocol such as those may utilize similar frequency ranges but proprietary modulation and data transmission characteristics. In embodiments, Bluetooth ®, BLE, proprietary RF protocol, or other WPAN or WLAN protocols and plural such protocols may be used for communication with and among any wireless peripheral devices withing a radiofrequency environment with radiofrequency signals for wireless communications among the information handling system 100 or other information handling systems or wireless devices. In the context of the present disclosure the one or more antennas 140 may include one or more WiFi antennas operating at 2.4 GHz, 5 GHz, and/or 6 GHz frequencies, one or more Bluetooth antennas, and one or more 5G new radio (5G-NR) antennas that operate at Frequency Range 1 (FR1) (which includes sub-7 GHz frequency bands and those from 410 MHz to 7125 MHz 0 and Frequency Range 2 (FR2) (which includes frequency bands from 24.25 GHz to 71.0 GHz frequency bands). It is appreciated that the one or more antennas 140 may support any frequency or frequency range and the present specification appreciates the use of these other types of antennas 140.

In other embodiments, the wireless interface device 134 with its radio 136, RF front end 138 and antennas 140 are used to communicate with a WWAN or and WLAN which may each include an AP 144 or base station 146 used to operatively couple the information handling system 100 to a network 142 via the wireless interface adapter 134 in a radiofrequency environment. In a specific embodiment, the network 142 may include macro-cellular connections via one or more base stations 146 or a wireless AP 144 (e.g., Wi-Fi), or such as through licensed or unlicensed WWAN small cell base stations 146. Connectivity may be via wired or wireless connection. For example, wireless network wireless APs 144 or base stations 146 may be operatively connected to the information handling system 100. Wireless interface adapter 134 may include one or more RF (RF) subsystems (e.g., radio 136) with transmitter/receiver circuitry, modem circuitry, one or more antenna RF (RF) front end 138 circuits, one or more wireless controller circuits, amplifiers, antennas 140 and other circuitry of the radio 136 such as one or more antenna ports used for wireless communications via multiple radio access technologies (RATs). The radio 136 may communicate with one or more wireless technology protocols. It is appreciated that the information handling system 100 may wirelessly communicate with a target receiver device 178 via the reconfigurable metasurface unit cell array 162. The receiver device 178 may be any other device and may include the AP 144, the base station 146, or any other computing device described herein. Additionally, the information handling system 100 and receiver device 178 may be capable of transmitting wireless data using, for example, EM waves that include 5G mm wave lengths such as those included within the 20-50 GHz range or WiFi wavelengths such as 2.4 GHz, 5 GHz, 6 GHz or others to be used with later versions of WiFi. Thus, in an embodiment, the reconfigurable metasurface unit cell array 162 is capable of relaying these types of mm waves.

In an embodiment, the wireless interface adapter 134 may operate in accordance with any wireless data communication standards. To communicate with a wireless local area network and/or the receiver device 178, standards including IEEE 802.11 WLAN standards (e.g., IEEE 802.11ax-2021 (Wi-Fi 6E, 6 GHz)), IEEE 802.15 WPAN standards, WWAN such as 3GPP or 3GPP2, Bluetooth® standards, proprietary RF protocol, or similar wireless standards may be used. Wireless interface adapter 134 may connect to any combination of macro-cellular wireless connections including 2G, 2.5G, 3G, 4G, 5G or the like from one or more service providers. Utilization of RF communication bands according to several example embodiments of the present disclosure may include bands used with the WLAN standards and WWAN carriers which may operate in both licensed and unlicensed spectrums. The wireless interface adapter 134 can represent an add-in card, wireless network interface module that is integrated with a main board of the information handling system 100 or integrated with another wireless network interface capability, or any combination thereof.

In some embodiments, a hardware processing resource executes machine readable code instructions of software or firmware to implement one or more of some systems and methods described herein, or dedicated hardware implementations such as application specific integrated circuits, programmable logic arrays and other hardware devices may be constructed to implement one or more of some systems and methods described herein. Applications that may include the apparatus and systems of various embodiments may broadly include a variety of electronic and computer systems. One or more embodiments described herein may implement functions using two or more specific interconnected hardware devices with related control and data signals that may be communicated between and through the modules, or as portions of an application-specific integrated circuit (ASIC). Accordingly, the present system encompasses a hardware processing resource executing machine readable code instructions of software or firmware as well as hardware implementations or any combination.

In accordance with various embodiments of the present disclosure, the methods described herein may be implemented by firmware or software programs executable by a hardware controller or a hardware processor system. Further, in an exemplary, non-limited embodiment, implementations may include distributed hardware processing, component/object distributed hardware processing, and parallel hardware processing. Alternatively, virtual computer system processing may be constructed to implement one or more of the methods or functionalities as described herein.

The present disclosure contemplates a computer-readable medium that includes machine readable code instructions, parameters, and profiles 118 or receives and executes machine readable code instructions, parameters, and profiles 118 responsive to a propagated signal, so that a hardware device connected to a network 142 may communicate voice, video, or data over the network 142. Further, the machine readable code instructions, parameters, and profiles 118 may be transmitted or received over the network 142 via the network interface device or wireless interface adapter 134.

The information handling system 100 may include a set of machine readable code instructions, parameters, and profiles 118 that may be executed to cause the computer system to perform any one or more of the methods or computer-based functions disclosed herein. For example, machine readable code instructions, parameters, and profiles 118 may be executed by a hardware processor 102, GPU 106, EC 104, APU 108, NPU 110, or any other hardware processing resource and may include software agents, or other aspects or components used to execute the methods and systems described herein. Various software modules comprising application machine readable code instructions, parameters, and profiles 118 may be coordinated by an operating system (OS) 122, and/or via an application programming interface (API) include a unified device API described herein. An example OS 122 may include Windows ®, Android ®, and other OS types. Example APIs may include Win 32, Core Java API, or Android APIs.

In an embodiment, the information handling system 100 may include a disk drive unit 126. The disk drive unit 126 and may include machine-readable program code instructions, parameters, and profiles 118 in which one or more sets of machine-readable program code instructions, parameters, and profiles 118 such as firmware or software can be embedded to be executed by the hardware processor 102 (e.g., CPU) or other hardware processing devices such as a GPU 106, an EC 104, an NPU 110, an APU 108, or other hardware processing resource device to perform the processes described herein. Similarly, main memory 112 and static memory 114 may also contain a computer-readable medium for storage of one or more sets of machine-readable program code instructions, parameters, or profiles 118 described herein. The disk drive unit 126 or static memory 114 also contain space for data storage. Further, the machine-readable program code instructions, parameters, and profiles 118 may embody one or more of the methods as described herein. In a particular embodiment, the machine-readable program code instructions, parameters, and profiles 118 may reside completely, or at least partially, within the main memory 112, the static memory 114, and/or within the disk drive 126 during execution by the hardware processor 102, EC 104, APU 108, NPU 100, or GPU 106 of information handling system 100.

Main memory 112 or other memory of the embodiments described herein may contain computer-readable medium (not shown), such as RAM in an example embodiment. An example of main memory 112 includes random access memory (RAM) such as static RAM (SRAM), dynamic RAM (DRAM), non-volatile RAM (NV-RAM), or the like, read only memory (ROM), another type of memory, or a combination thereof. Static memory 114 may contain computer-readable medium (not shown), such as NOR or NAND flash memory in some example embodiments. The applications and associated APIs, for example, may be stored in static memory 114 or on the disk drive unit 126 that may include access to a machine-readable code instructions, parameters, and profiles 118 such as a magnetic disk or flash memory in an example embodiment. While the computer-readable medium is shown to be a single medium, the term “computer-readable medium” includes a single medium or multiple media, such as a centralized or distributed database, and/or associated caches and servers that store one or more sets of machine-readable code instructions. The term “computer-readable medium” shall also include any medium that is capable of storing, encoding, or carrying a set of machine-readable code instructions for execution by a processor or that cause a computer system to perform any one or more of the methods or operations disclosed herein.

In an embodiment, the information handling system 100 may further include a power management unit (PMU) 128 (a.k.a. a power supply unit (PSU)). The PMU 128 may include a hardware controller and executable machine-readable code instructions to manage the power provided to the components of the information handling system 100 such as the hardware processor 102 and other hardware components described herein. The PMU 128 may control power to one or more components including the one or more drive units 126, the hardware processor 102 (e.g., CPU), the EC 104, the GPU 106, the APU 108, the NPU 110, the video/graphic or digital display device 150, or other wired or wireless I/O devices 148 such as the mouse 158, the stylus 154, the keyboard 152, and the trackpad 156 and other components that may require power when a power button has been actuated by a user. In an embodiment, the PMU 128 may monitor power levels and be electrically coupled to the information handling system 100 in embodiments herein to provide this power. The PMU 128 may be coupled to the bus 124 to provide or receive data or machine-readable code instructions. The PMU 128 may regulate power from a power source such as the battery 130, or AC power adapter 132. In an embodiment, the battery 130 may be charged via the AC power adapter 132 and provide power to the components of the information handling system 100, via wired connections, or when AC power from the AC power adapter 132 is removed.

In a particular non-limiting, exemplary embodiment, the computer-readable medium can include a solid-state memory such as a memory card or other package that houses one or more non-volatile read-only memories. Further, the computer-readable medium can be a random-access memory or other volatile re-writable memory. Additionally, the computer-readable medium can include a magneto-optical or optical medium, such as a disk or tapes or other storage device to store information received via carrier wave signals such as a signal communicated over a transmission medium. Furthermore, a computer readable medium 116 can store information received from distributed network resources such as from a cloud-based environment. A digital file attachment to an e-mail or other self-contained information archive or set of archives may be considered a distribution medium that is equivalent to a tangible storage medium. Accordingly, the disclosure is considered to include any one or more of a computer-readable medium or a distribution medium and other equivalents and successor media, in which data or machine-readable code instructions may be stored.

In other embodiments, dedicated hardware implementations such as application specific integrated circuits (ASICs), programmable logic arrays and other hardware devices can be constructed to implement one or more of the methods described herein. Applications that may include the apparatus and systems of various embodiments can broadly include a variety of electronic and computer systems. One or more embodiments described herein may implement functions using two or more specific interconnected hardware modules or devices with related control and data signals that can be communicated between and through the modules, or as portions of an application-specific integrated circuit. Accordingly, the present system encompasses hardware resources executing software or firmware, as well as hardware implementations.

As described herein, the information handling system 100 may be one of many such devices within a radiofrequency environment. In an embodiment, the information handling system 100 may initiate wireless transmissions via a wireless interface adapter as described herein. As such, the information handling system 100 may interact, wirelessly, with the reconfigurable metasurface unit cell array 162 such that the reconfigurable metasurface unit cell array 162 can relay those wireless transmissions to a receiving device such as an access point 144 or another network device in the radiofrequency environment. In an embodiment, the reconfigurable metasurface unit cell array 162 may be affixed to a surface within the radiofrequency environment such that wireless transmissions may be reflected off of the surface of the reconfigurable metasurface unit cell array 162. In other embodiments, the reconfigurable metasurface unit cell array 162 may be standalone affixed to a surface of an information handling system 100 in the radiofrequency environment such that wireless transmissions may be reflected off of the surface of the reconfigurable metasurface unit cell array 162 at an information handling system 100.

The reconfigurable metasurface unit cell array 162 may, in an embodiment, include a metasurface power management unit (PMU) 166. The metasurface PMU 166 may be a power source used to power the devices, circuits, and elements operatively coupled to and/or formed onto the reconfigurable metasurface unit cell array 162. The devices, circuits, and elements operatively coupled to and/or formed onto the reconfigurable metasurface unit cell array 162 may include centralized metasurface hardware controller 164, metasurface memory device 184, metasurface NPU 180 (if separate), embedded metasurface microcontrollers 174-1, 174-2, attenuator circuits 175-1, 175-2 and tunable delay circuits 177-1, 177-2 that are powered by the metasurface PMU 166 in some embodiments. In an embodiment, the metasurface PMU 166 may include a metasurface battery 168 that is used by the metasurface PMU 166 to power, with low power, those devices on the reconfigurable metasurface unit cell array 162. Alternatively, and in another embodiment, the metasurface PMU 166 may include a metasurface A/C power adapter 170 that regulates power received from an A/C power source. Again, the reconfigurable metasurface unit cell array 162 including the devices, circuits, and elements operatively coupled to and/or formed onto the reconfigurable metasurface unit cell array 162 require low power for operation according to some embodiments herein.

In an embodiment, the reconfigurable metasurface unit cell array 162 includes a plurality of metasurface unit cells 178-1, 178-2, 178-3, 178-4 shown in FIG. 1 to include, at least, a first metasurface unit cell 178-1, a second metasurface unit cell 178-2, a third metasurface unit cell 178-3, and a fourth metasurface unit cell 178-4. It is appreciated, however, that the reconfigurable metasurface unit cell array 162 may include more than the first metasurface unit cell 178-1, second metasurface unit cell 178-2, third metasurface unit cell 178-3, and fourth metasurface unit cell 178-4 shown in FIG. 1. In an embodiment, the reconfigurable metasurface unit cell array 162 may include an array of metasurface unit cells 178-1, 178-2, 178-3, 178-4 arranged in rows and columns within, for example, one or more metasurface unit cell subgroups 176-1 or 176-2 of the reconfigurable metasurface unit cell array 162. In one example embodiment, each metasurface unit cell subgroup 176-1 or 176-2 may include a nine by nine array of metasurface unit cells 178-1, 178-2, 178-3, 178-4. It is appreciated, however, that any arrangement and any number of metasurface unit cells 178-1, 178-2, 178-3, 178-4 may be used to form the reconfigurable metasurface unit cell array 162 described herein. As shown in FIG. 1, an example of these metasurface unit cell subgroups 176-1, 176-2 includes the first metasurface unit cell 178-1 and second metasurface unit cell 178-2 among a plurality of metasurface unit cells that form the first metasurface unit cell subgroup 176-1, and the third metasurface unit cell 178-3 and fourth metasurface unit cell 178-4 being two of a plurality of metasurface unit cells that form a second metasurface unit cell subgroup 176-2. In an embodiment, each metasurface unit cell subgroup 176-1, 176-2 may include nine metasurface unit cells 178-1, 178-2, 178-3, 178-4 with each metasurface unit cell subgroup 176-1, 176-2 being operatively coupled to a metasurface embedded microcontroller 174-1, 174-2 that controls the operation of each of the metasurface unit cell subgroups 176-1, 176-2 respectively and, in an embodiment, each of the metasurface unit cells 178-1, 178-2, 178-3, 178-4 within its subgroup individually. Thus, in an embodiment, a first metasurface embedded microcontroller 174-1 may control the metasurface unit cells 178-1, 178-2 of the first metasurface unit cell subgroup 176-1 and a second metasurface embedded microcontroller 174-2 may control the metasurface unit cells 178-3, 178-4 within the second metasurface unit cell subgroup 176-2. In an embodiment, each of the metasurface embedded microcontrollers 174-1, 174-2 may be directed by the operation of the centralized metasurface hardware controller 164 that manages workload distribution among the metasurface embedded microcontrollers 174-1, 174-2. In some embodiments, the centralized metasurface hardware controller 164 executes machine readable code instructions of a Deep Reinforcement Learning (DRL) algorithm 183 to directed and manages workload distribution among the metasurface embedded microcontrollers 174-1, 174-2 in control of adjusting first and second metasurface unit cell subgroups 176-1 and 176-2. In embodiments herein, the centralized metasurface hardware controller 164 executes machine readable code instructions of a Deep Reinforcement Learning (DRL) algorithm 183 along with output from machine readable code instructions of the cGAN algorithm 181 for generating filtered offset radiofrequency signal and adjusting first and second metasurface unit cell subgroups 176-1 and 176-2 via each of the metasurface embedded microcontrollers 174-1, 174-2.

It is appreciated that although FIG. 1 shows two metasurface unit cell subgroups 176-1, 176-2 with their respective metasurface embedded microcontrollers 174-1, 174-2, the present specification contemplates that more than the two metasurface unit cell subgroups 176-1, 176-2 may be formed into the reconfigurable metasurface unit cell array 162. In an embodiment, the reconfigurable metasurface unit cell array 162 may be formed by arranging the metasurface unit cell subgroups 176-1, 176-2 in columns and rows of metasurface unit cell subgroups 176-1, 176-2 in a wider reconfigurable metasurface unit cell array 162.

In an embodiment, each metasurface unit cell 178-1, 178-2, 178-3, 178-4 may be operatively controlled by their respective metasurface embedded microcontroller 174-1, 174-2 at the metasurface unit cell subgroup 176-1, 176-2. In an embodiment, the metasurface embedded microcontrollers 174-1, 174-2 may control the operation of each of the metasurface unit cells 178-1, 178-2, 178-3, 178-4 and/or a metasurface unit cell subgroups 176-1, 176-2 within the reconfigurable metasurface unit cell array 162 using one or more attenuator circuits 175-1, 175-2 and or one or more tunable delay circuits 177-1, 177-2 in various embodiments. For ease of understanding, the operation of the respective metasurface embedded microcontroller 174-1, 174-2, attenuator circuit 175-1, 175-2, and tunable delay circuit 177-1, 177-2 will be described as controlling a single metasurface unit cell subgroup 176-1, 176-2 within the reconfigurable metasurface unit cell array 162. It is appreciated, however, that a single metasurface embedded microcontroller 174-1, 174-2 may control the operation of a single attenuator circuit 175-1, 175-2 and tunable delay circuit 177-1, 177-2 for a metasurface unit cell subgroup 176-1, 176-2 among a plurality of subgroups of metasurface unit cells 178-1, 178-2, 178-3, 178-4 within the reconfigurable metasurface unit cell array 162 in various embodiments. The one or more tunable delay circuits 177-1, 177-2 may operate with tunable variable capacitance (e.g., varactors) or variable resistance in a microwave circuit to impart phase delay in a filtered offset radiofrequency signals for re-sending to resonating elements of the metasurface unit cells 178-1, 178-2, 178-3, 178-4 in embodiments herein. The one or more attenuator circuits 175-1, 175-2 may operate with resistance network, such as voltage dividers, which may be tunable (e.g., variable resistors) in a microwave circuit to impart amplitude adjustment in filtered offset radiofrequency signals re-sent to resonating elements of the metasurface unit cells 178-1, 178-2, 178-3, 178-4 such that gain may be maximized or amplitude cancellation enabled with equal amplitude to the incident radiofrequency signal or equal and opposite amplitude to the interference signal in the filtered offset radiofrequency signals in embodiments herein. It is understood that this gain or reduction in amplitude may be variable for control of gain or cancellation, or that amplitude may not always be exactly equal in various embodiments herein.

Each of the metasurface unit cells 178-1, 178-2, 178-3, 178-4 may include a passive concentric resonating antennas or resonating structures that are sized and spaced to resonate with incident EM waves of radiofrequency signals propagated from an antenna source within the radiofrequency environment such as the antenna 140 of the information handling system 100. The metasurface unit cells 178-1, 178-2, 178-3, 178-4 may include a conductive fixed tab within the conductive concentric antennas formed onto a dielectric substrate in an embodiment. Further, while specific concentric antennas are discussed in embodiments herein, any shape of concentric antennas for the passive resonating structure portions of the metasurface unit cells 178-1, 178-2, 178-3, 178-4 may be used. These passive concentric resonating antennas of the metasurface unit cells 178-1, 178-2, 178-3, 178-4 may receive those incident EM waves of radiofrequency signals and transfer the EM wave resonance through a partial signal coupler and to a radio frequency (RF)/electromagnetic (EM) circuit network coupler placed below the passive concentric resonating antennas of each metasurface unit cells 178-1, 178-2, 178-3, 178-4. The RF/EM circuit network of each metasurface unit cells 178-1, 178-2, 178-3, 178-4 act as a coupler to capture the EM waves and links to the processing units that manipulate the captured EM wave energy from the passive concentric resonating antennas and partial signal couplers with these signals being sent initially to the metasurface embedded microcontroller 174-1, 174-2.

During operation, the centralized metasurface hardware controller 164 may receive and derive data describing those wireless transmissions within the wireless network from those radiofrequency signals incident to the reconfigurable metasurface unit cell array 162 in the radiofrequency environment. In an embodiment, the centralized metasurface hardware controller 164 may derive angle-of-arrival (AoA) data that describes a direction of any given incident radiofrequency signal relative to the surface of the reconfigurable metasurface unit cell array 162.

For example, during operation of the reconfigurable metasurface unit cell array 162, the partial signal coupler and RF/EM circuit network with coupling may be used by the centralized metasurface hardware controller 164 to determine this AoA data of the incident radiofrequency signals. In this embodiment, the passive concentric resonating antennas of each the metasurface unit cells 178-1, 178-2, 178-3, 178-4 have known dimension and spacing and may receive the incident radiofrequency signals and transfer the EM wave resonance through the partial signal coupler and to the RF/EM circuit network placed below the passive concentric resonating antennas of each metasurface unit cell 178-1, 178-2, 178-3, 178-4. In an embodiment, the partial signal coupler captures a portion of the incident radiofrequency signals received at the passive concentric resonating antennas and diverts this small portion or sample of the incident radiofrequency signals to the RF/EM circuit network. In an embodiment, the portion or sample of the incident radiofrequency signals may retain all phase, amplitude, frequency, and polarization information of each of the radiofrequency signals incident to the reconfigurable metasurface unit cell array 162, including interference components of the radiofrequency signals. The RF/EM circuit network placed below each of the metasurface unit cells 178-1, 178-2, 178-3, 178-4 may pass the partial signal received by the partial signal coupler to embedded metasurface microcontroller 174-1 or 174-2 and on to the centralized metasurface hardware controller 164 that can derive this AoA data related to the incident radiofrequency signals. In an example embodiment, the centralized metasurface hardware controller 164 may use the partial signals received from each of the plurality of metasurface unit cells 178-1, 178-2, 178-3, 178-4 and/or metasurface unit cell subgroups 176-1, 176-2, including delay and known dimension and spacing of those metasurface unit cells 178-1, 178-2, 178-3, 178-4 to determine the AoA from a transmitting wireless device in the radiofrequency environment. Because the metasurface unit cells 178-1, 178-2, 178-3, 178-4 and/or metasurface unit cell subgroups 176-1, 176-2 are spatially separated from each other at known distances and have known dimension, the incident radiofrequency signals will reach each of the metasurface unit cells 178-1, 178-2, 178-3, 178-4 and/or metasurface unit cell subgroups 176-1, 176-2 at different times creating phase differences between the detected partial signals received at the RF/EM circuit network. Using this data, the AoA data may be computed by the centralized metasurface hardware controller 164. Similarly, the centralized metasurface hardware controller 164 may calculate the angle-of-departure (AoD) using, for example, a multiple signal classification (MUSIC) algorithm, or an estimation of a signal parameters via rotational invariance technique (ESPIRIT) algorithm. Other AoD determinative algorithms may be used to determine AoD from the AoA data for a radiofrequency signal in embodiments herein. Also, based on an embedded signal of the incident radiofrequency signals, the centralized metasurface hardware controller 164 may also determine the time-of-flight (ToF) data of the incident radiofrequency signals.

As the centralized metasurface hardware controller 164 calculates the AoA data, the AoD data, and the ToF data the centralized metasurface hardware controller 164 may also execute machine readable code instructions of a signal feature extraction and preprocessing module 172. The execution of the signal feature extraction and preprocessing module 172 may, in an example embodiment, causes the centralized metasurface hardware controller 164 to determine and identify the AoA data, the AoD data, and the ToF data for radiofrequency signals incident on the reconfigurable metasurface unit cell array 162 described herein. Additionally, the execution of the signal feature extraction and preprocessing module 172 may also convert the time-domain signals of the captured incident radiofrequency signals into frequency domain using, for example, a Fourier transform algorithm executed by the centralized metasurface hardware controller 164. Execution of machine readable code instructions of the Fourier transform algorithm is conducted to decompose and breakdown the captured incident radiofrequency signal in order to identify those wireless communication radiofrequency signal components and consistent ongoing interference components of the captured incident radiofrequency signal from the various frequencies as well as certain spectral features associated with those detected frequencies within the captured incident radiofrequency signal. Execution of the signal feature extraction and preprocessing module 172, in an embodiment, may also cause the metasurface controller 164 to further decompose or otherwise break the signal down into components with varying frequency and time resolution that is later used in identifying transient interference. For example, the execution of the signal feature extraction and preprocessing module 172 may execute a wavelet transform algorithm that breaks the signal down into components to identify how each identified frequency components of the captured incident radiofrequency signal evolve over time and those spurious portions and interference signals within the captured incident radiofrequency signal in real-time and which may have resulted from, for example, transient events (e.g., movements of objects) within the radiofrequency environment. In an embodiment, the execution of the wavelet transform algorithm may identify time-localized frequency variations within the captured incident radiofrequency signal from the radiofrequency environment. Thus, in an embodiment, the signal feature extraction and preprocessing module 172 may first apply the Fourier transform algorithm to the captured incident radiofrequency signal to identify an overview of the captured incident radiofrequency signal's global frequency content and then execute a wavelet transform algorithm to identify time-localized frequency details within those identified frequencies within the captured incident radiofrequency signal. In an embodiment, the conversion into frequency domain and the decomposition of the signal into components with varying frequency and time resolution may ensure that the input data to the cGAN algorithm 182 that can be used to determine what should be filtered as well as improve training stability and performance of the systems and methods described herein.

It is appreciated that, in an embodiment, this data related to the AoA, AoD, ToF, frequency domain data, signal components with varying frequency and time resolution for transient interference, interference components and wireless communication radiofrequency signals may be described, generally, as those feature characteristics of the captured incident radiofrequency signals incident to the surface of the reconfigurable metasurface unit cell array 162. Along with deriving and identifying this data, the centralized metasurface hardware controller 164 may also execute computer-readable program code of a deep reinforcement learning (DRL) algorithm. Execution of the DRL algorithm allows the centralized metasurface hardware controller 164 to effectively manage each of the metasurface embedded microcontrollers 174-1, 174-2 associated with each of the metasurface unit cell subgroups 176-1, 176-2 thereby managing workloads distributed among the metasurface embedded microcontrollers 174-1, 174-2 to ensure scalability and low-latency feedback in data transmissions in adjustments at those metasurface unit cell subgroups 176-1, 176-2 for a filtered offset radiofrequency signal used to mitigate interference in the reflected radiofrequency signal. Thus, in an embodiment, portions of the processing requirements during the operation of the reconfigurable metasurface unit cell array 162 may be distributed among a plurality of hardware processing devices allowing for real-time evaluation of the incident radiofrequency signals and generation of the filtered offset radiofrequency signal used for interference mitigation during any given wireless transmission within the wireless network relayed by the reconfigurable metasurface unit cell array 162 in the radiofrequency environment.

As described herein, as the feature characteristics extracted from the captured incident radiofrequency signals (e.g., AoA, AoD, ToF, frequency domain data, signal components with varying frequency and time resolution, etc.) are derived by the centralized metasurface hardware controller 164 executing machine readable code instructions of various modules including the signal feature extraction and preprocessing module, and the centralized metasurface hardware controller 164 may transmit this data to a metasurface neural processing unit (NPU) 180 that may be separate or an NPU 180 portion of the centralized metasurface hardware controller 164. The metasurface NPU 180 may be responsible for executing computer-readable program code of a conditional generative adversarial network (cGAN) algorithm 182. The cGAN algorithm 182 may actively filter out unwanted interference from the portion of captured incident radiofrequency signals by predicting and removing spurious interference portions of the signal in real-time and filtering out identified consistent interference signals. In an embodiment, the cGAN algorithm 182 may receive a number of different inputs in order to accomplish this. A first input may include the raw incident radiofrequency signals sent from each of the metasurface unit cell subgroups 176-1, 176-2. Another input may include each of the feature characteristics extracted for components of the captured incident radiofrequency signals described herein. Yet another input may include random noise generated by a noise generator. The cGAN algorithm 182 may then, through the use of a plurality of neural networks, generate a filtered offset radiofrequency signal that, when combined with the incident radiofrequency signals being reflected, causes the filtered offset radiofrequency signal with wireless communication component to be amplified at the reconfigurable metasurface unit cell array 162 while the unwanted distortion is muted. In an embodiment, the cGAN algorithm 182 includes a generator neural network that is taught to create the filtered offset radiofrequency signal that, when combined with the incident radiofrequency signals, cancels out the interference within the signal. Still further the cGAN algorithm 182 also includes a discriminator neural network that evaluates how well the generator neural network is performing by distinguishing between corrected signals and the wanted, interference-free signals within the incident radiofrequency signals.

In an embodiment the generator neural network of the cGAN algorithm 182 may use, as input, the AoA data, the AoD data, and the ToF data to estimate how multipath interference may affect the received incident radiofrequency signals. The frequency and time-frequency data may be used as input to the generator neural network of the cGAN algorithm 182 to detect distortions at different spectral and temporal levels. Additionally, the generator neural network of the cGAN algorithm 182 may use the random noise input to generate a diversity of filtered signals for robustness and compare those diverse filtered signals to the incident radiofrequency signals received.

In an embodiment, the discriminator neural network of the cGAN algorithm 182 may be trained to differentiate between the wanted, interference free signals and the generated signals from the noise generator. In an embodiment, the discriminator neural network of the cGAN algorithm 182 may evaluate the spectral purity of the filtered offset radiofrequency signal and time domain consistency and provide feedback to the noise generator in order to improve the filtering accuracy of the cGAN algorithm 182. The discriminator neural network of the cGAN algorithm 182 may therefore ensure that the generated filtered offset radiofrequency signal is optimized to have limited or no interference. The execution of the cGAN algorithm 182, in an embodiment, provides as output a cleaned up and filtered offset radiofrequency signal as described herein. It is appreciated that any type of cGAN algorithm 182 may be used in the present system and method and the specification contemplates the use of these other types of cGAN algorithms 182.

After the cGAN algorithm 182 has generated the filtered offset radiofrequency signal, the filtered offset radiofrequency signal may be transmitted to the centralized metasurface hardware controller 164 for the centralized metasurface hardware controller 164 to relay the filtered offset radiofrequency signal to each of the metasurface embedded microcontrollers 174-1, 174-2 associated with and controlling the operation of each of the metasurface unit cell subgroups 176-1, 176-2. Each of the metasurface embedded microcontrollers 174-1, 174-2 may be responsible for local processing of the filtered offset radiofrequency signal with respect to phase-shift and may be directed how to process the filtered offset radiofrequency signal from the centralized metasurface hardware controller 164 for retransmission within a reflected radiofrequency signal across the corresponding metasurface unit cell subgroups 176-1, 176-2. Thus, in an embodiment, the centralized metasurface hardware controller 164 may direct correction parameters to be applied to the filtered offset radiofrequency signal received by each of the metasurface embedded microcontrollers 174-1, 174-2 that may vary from one metasurface embedded microcontroller 174-1, 174-2 to another to provide for beamforming and amplitude gain of the wireless communication radiofrequency signal components and suppression of the interference noise components. This may be done so that the appropriate beamforming parameters, attenuation, and phase shifting may be applied to the filtered offset radiofrequency signal across each of the metasurface unit cell subgroups 176-1, 176-2 in the reconfigurable metasurface unit cell array 162. For example, each of the metasurface embedded microcontrollers 174-1, 174-2 may be provided with high-level signal correction data to be applied to the filtered offset radiofrequency signal thereby allowing each metasurface embedded microcontroller 174-1, 174-2 to interact with an attenuator circuit 175-1, 175-2 and tunable delay circuit 177-1, 177-2 in order to concurrently execute interference cancellation, beamforming, and beamsteering at corresponding metasurface unit cell subgroups 176-1, 176-2 across the reconfigurable metasurface unit cell array 162. For example, each of the metasurface embedded microcontrollers 174-1, 174-2 may access an attenuator circuit 175-1, 175-2 that reduces or matches equal and opposite amplitude of undesired spurious signal components in the filtered offset radiofrequency signal, enhances the amplitude of the desired components of the filtered offset radiofrequency signal, and sends this amplitude-adjusted filtered offset radiofrequency signal to a tunable delay circuit 177-1, 177-2 associated with the metasurface embedded microcontroller 174-1, 174-2.

The tunable delay circuits 177-1, 177-2 associated with each metasurface embedded microcontroller 174-1, 174-2 may time-align the filtered offset radiofrequency signal so that when it combines with the original incident radiofrequency signals at the surface of the reconfigurable metasurface unit cell array 162 it results in destructive interference for unwanted signal components and constructive interference for desired signal components such as the wireless communication radiofrequency signal component. For example, each tunable delay circuit 177-1, 177-2 may specifically apply a tunable delay in order to synchronize the phase of the filtered offset radiofrequency signal with the incident radiofrequency signals such that if beamforming is required, the tunable delay circuits 177-1, 177-2 apply a phase shift across metasurface unit cell subgroups 176-1, 176-2 using constructive or destructive interference of the radiofrequency signal to steer the filtered offset radiofrequency signal with the reflected radiofrequency signal in the desired direction by adjusting the phase across the metasurface unit cells 178-1, 178-2, 178-3, 178-4.

When the metasurface embedded microcontrollers 174-1, 174-2 have applied the appropriate attenuation and phase shifting of the filtered offset radiofrequency signal, the metasurface embedded microcontroller 174-1, 174-2 may cause the filtered offset radiofrequency signal to be sent to the RF/EM circuit network for the RF/EM circuit network to reintroduce that filtered offset radiofrequency signal into resonant structures, such as concentric antennas, of the reconfigurable metasurface unit cell array 162 so that the filtered offset radiofrequency signal can interact with the reflection of original incident radiofrequency signals. Thus, if the filtered offset radiofrequency signal is properly phase-aligned for cancellation of unwanted interference, the filtered offset radiofrequency signal combines with unwanted interference components of the original incident radiofrequency signals thereby causing destructive interference and removing unwanted interference. Additionally, where the filtered offset radiofrequency signal is phase-aligned to reinforce the desired signal, it constructively interferes with the original incident radiofrequency signals thereby enhancing gain in the desired direction increasing the EM radiofrequency signal lobe of the wireless communication component in the reflected radiofrequency signal. Indeed, by operation of the metasurface embedded microcontrollers 174-1, 174-2 and centralized metasurface hardware controller 164 and by tuning the phase shifts across multiple metasurface unit cells 178-1, 178-2, 178-3, 178-4, the reconfigurable metasurface unit cell array 162 steers the EM radiofrequency signal lobe toward the intended receiver. This improves signal clarity, quality, and strength and increases data transmission efficiency within the wireless network at the reconfigurable metasurface unit cell array 162.

The system and methods described herein provide for a reconfigurable metasurface unit cell array 162 with integrated intelligence in the form of a cGAN algorithm 182 that actively filters out unwanted interference from the incident radiofrequency signals by identifying and predicting and removing spurious interference portions or cancelling consistent interference signals. The cGAN algorithm 182 does this in real-time thereby enhancing the effectiveness of the reconfigurable metasurface unit cell array 162. Additionally, a centralized metasurface hardware controller 164 uses a DRL algorithm to efficiently manage workload distribution among metasurface embedded microcontrollers 174-1, 174-2 and metasurface unit cell subgroups 176-1, 176-2 thereby ensuring scalability and low-latency feedback. The metasurface embedded microcontrollers 174-1, 174-2 may be situated on-device at the reconfigurable metasurface unit cell array 162 and implements corrections determined by the cGAN algorithm 182. The metasurface embedded microcontrollers 174-1, 174-2 also actively manage reflection of the radiofrequency signal by the reconfigurable metasurface unit cell array 162 by amplifying the required portions and absorbing the interference.

When referred to as a “system,” a “device,” a “module,” a “controller,” or the like, the embodiments described herein can be configured as hardware. For example, a portion of an information handling system device may be hardware such as, for example, an integrated circuit (such as an Application Specific Integrated Circuit (ASIC), a Field Programmable Gate Array (FPGA), a structured ASIC, or a device embedded on a larger chip), a card (such as a Peripheral Component Interface (PCI) card, a PCI-express card, a Personal Computer Memory Card International Association (PCMCIA) card, or other such expansion card), or a system (such as a motherboard, a system-on-a-chip (SoC), or a stand-alone device). The system, device, controller, or module can include hardware processing resources executing software, including firmware embedded at a device, such as an Intel ® brand processor, AMD ® brand processors, Qualcomm ® brand processors, or other processors and chipsets, or other such hardware device capable of operating a relevant software environment of the information handling system. The system, device, controller, or module can also include a combination of the foregoing examples of hardware or hardware executing software or firmware. Note that an information handling system can include an integrated circuit or a board-level product having portions thereof that can also be any combination of hardware and hardware executing software. Devices, modules, hardware resources, or hardware controllers that are in communication with one another need not be in continuous communication with each other, unless expressly specified otherwise. In addition, devices, modules, hardware resources, and hardware controllers that are in communication with one another can communicate directly or indirectly through one or more intermediaries.

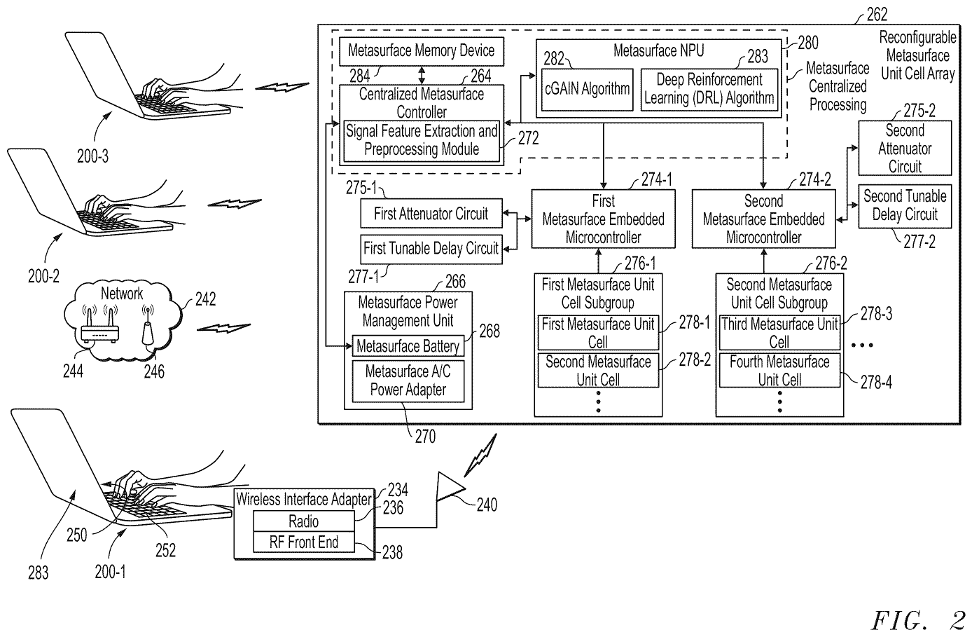

FIG. 2 is a block diagram illustrating a plurality of information handling systems 200-1, 200-2, 200-3 and a reconfigurable metasurface unit cell array 262 comprising a plurality of metasurface unit cells 278-1, 278-2, 278-3, 278-4 operatively controlled by a centralized metasurface hardware controller 264 that mitigates radiofrequency signal interference in radiofrequency signals within a wireless network 242 in a radiofrequency environment according to another embodiment of the present disclosure. FIG. 2 shows the information handling systems 200-1, 200-2, 200-3 as laptop-type information handling systems 200-1, 200-2, 200-3 that may each include a digital display device 250 and a keyboard 252 as an output and input device, respectively. FIG. 2 further shows an access point 244 and base station 246 within the wireless network 242 as parts of the radiofrequency environment. It is appreciated that those network devices that include these information handling systems 200-1, 200-2, 200-3, access point 244, and base station 242 may be any type of information handling system described herein and may be both transmitting and receiving devices that transceive wireless communications via radiofrequency signal transmissions using the reconfigurable metasurface unit cell array 262 described herein to relay those transceptions in the radiofrequency environment.

As described herein, the reconfigurable metasurface unit cell array 262 may be used within a wireless network to reflect incoming wireless transmissions off of its surface and around objects. This allows for smaller wavelength radio frequencies to be used within the wireless network 242 that can transmit large amounts of data. These shorter wavelength radio frequencies have a limited range especially through objects and degrade over long distances. In an embodiment, the reconfigurable metasurface unit cell array 262 may be many of a plurality of reconfigurable metasurface unit cell arrays 262 placed within a given area of the wireless network 242 in order to facilitate the relay of these type of wireless radiofrequency signal transmissions in a radiofrequency environment.

As described herein, the reconfigurable metasurface unit cell array 262 may include a plurality of metasurface unit cells 278-1, 278-2, 278-3, 278-4 that may be separated into one or more metasurface unit cell subgroups 276-1, 276-2 (e.g., first metasurface unit cell subgroup 290-1, second metasurface unit cell subgroup 290-2, etc.) that are each controlled by a metasurface embedded microcontroller 274-1, 274-2. Each of the metasurface embedded microcontrollers 274-1, 274-2 may be controlled by the centralized metasurface hardware controller 264. In order to control the operation of each of the metasurface unit cells 288-1, 288-2, 288-3, 288-4 within the each of the metasurface unit cell subgroups 276-1, 276-2, each of the metasurface embedded microcontrollers 274-1, 274-2 may control the operation of a respective attenuator circuits 275-1, 275-2 and a respective tunable delay circuit 277-1, 277-2 to manipulate radiofrequency signals at the metasurface unit cells 288-1, 288-2, 288-3, 288-4 within the each of the metasurface unit cell subgroups 276-1, 276-2 in various embodiments.

As described herein, various incident radiofrequency signals may interface with passive concentric resonating antennas of a size and spacing between resonating structures at each metasurface unit cell 278-1, 278-2, 278-3, 278-4 to resonate with the incident radiofrequency signals at the wavelengths propagated from an antenna source (e.g., AP 244, base station 246, information handling systems 200-1, 200-2, 200-3) within the wireless network(s) 242 in the radiofrequency environment. These passive concentric resonating antennas of the metasurface unit cells 278-1, 278-2, 278-3, 278-4 may receive those incident radiofrequency signals and transfer the EM wave resonance through a partial signal coupler and to a RF/EM circuit network placed below the passive concentric resonating antennas of each metasurface unit cells 278-1, 278-2, 278-3, 278-4. The RF/EM circuit network of each metasurface unit cells 278-1, 278-2, 278-3, 278-4 act as a coupler to capture partially coupled samples of the radiofrequency signals for the processing units that manipulate the captured EM wave energy of the captured radiofrequency signals from the passive concentric resonating antennas and partial signal couplers. These partial coupling captured radiofrequency signals are sent via the RF/EM circuit network to the embedded metasurface microcontrollers 274-1, 274-2 and on to the centralized metasurface hardware controller 264 at centralized metasurface processing for the reconfigurable metasurface unit cell array 262.

During operation, the metasurface hardware controller 264 may receive and derive data describing those captured radiofrequency signal samples partially coupled from incident radiofrequency signals from the wireless network 242 to the reconfigurable metasurface unit cell array 262. In an embodiment, during operation of the reconfigurable metasurface unit cell array 262, the partial signal coupler and RF/EM circuit network may be used by the metasurface hardware controller 264 to determine this AoA data of the incident radiofrequency signals. In this embodiment, the centralized metasurface hardware controller 264 may use the captured radiofrequency signals from the partial coupling received from each of the plurality of metasurface unit cells 278-1, 278-2, 278-3, 278-4 and/or metasurface unit cell subgroups 276-1, 276-2 for further processing to improve the reflected radiofrequency signals in amplitude and to reduce interference signals therein.

Because the metasurface unit cells 278-1, 278-2, 278-3, 278-4 and/or metasurface unit cell subgroups 276-1, 276-2 are spatially separated from each other by known distances and have known size, the captured incident radiofrequency signals at a particular wavelength will reach each of the metasurface unit cells 278-1, 278-2, 278-3, 278-4 and/or metasurface unit cell subgroups 276-1, 276-2 at different times creating phase differences between the detected partial signals received at the RF/EM circuit network. These phase differences of the delay of captured incident radiofrequency signals across the metasurface unit cells 278-1, 278-2, 278-3, 278-4 and/or metasurface unit cell subgroups 276-1, 276-2 are reported to the centralized metasurface hardware controller 264. Using this data, the centralized metasurface hardware processor 264 executes machine readable code instructions of a signal feature extraction and preprocessing module 272 to determine the AoA data for the captured incident radiofrequency signal as described herein.

Similarly, the metasurface hardware controller 264 executes machine readable code instructions of a signal feature extraction and preprocessing module 272 to determine the AoD using, for example, a MUSIC algorithm, an estimation of a ESPIRIT algorithm, or another algorithm for determining or estimating AoD from the calculated AoA above. Also, based on an embedded signal of the incident radiofrequency signals, the metasurface hardware controller 264 may also determine the ToF data of the incident radiofrequency signals coming from a transmitting wireless device in the radiofrequency environment in embodiments herein. This, ToF data may indicate time duration and, thus, distance, including intermediate hops or reflections, of the transmitting wireless device or of the receiving wireless device in the radiofrequency environment. This may indicate sources of distortion or interference that may be present in the incident radiofrequency signals received incident to the reconfigurable metasurface unit cell array.

As the metasurface hardware controller 264 calculates the AoA data, the AoD data, and the ToF data the metasurface hardware controller 264 may further execute machine readable code instructions of the signal feature extraction and preprocessing module 272 for additional feature characteristic extraction from the captured radiofrequency signal from the metasurface unit cell concentric resonating antennas. The execution of the signal feature extraction and preprocessing module 272 may, in an example embodiment, cause the metasurface hardware controller 264 to identify frequency domain of the incident radiofrequency signals (using, for example, a Fourier transform algorithm) from the time domain, and to identify wireless data transmission radiofrequency signal components and interference components, whether spurious or consistent and ongoing having varying frequency and time resolution, in the captured incident radiofrequency signal.

Execution of machine readable code instructions of the Fourier transform algorithm is conducted to decompose and breakdown the captured incident radiofrequency signal in order to identify those wireless communication radiofrequency signal components and consistent ongoing interference components of the captured incident radiofrequency signal from the various frequencies as well as certain spectral features associated with those detected frequencies within the captured incident radiofrequency signal. Execution of the signal feature extraction and preprocessing module 272, in an embodiment, may also cause the metasurface controller 164 to further decompose or otherwise break the signal down into components with varying frequency and time resolution that is later used in identifying transient interference. For example, the execution of the signal feature extraction and preprocessing module 272 may execute a wavelet transform algorithm that breaks the signal down into components to identify how each identified frequency components of the captured incident radiofrequency signal evolve over time and those spurious portions and interference signals within the captured incident radiofrequency signal in real-time and which may have resulted from, for example, transient events (e.g., movements of objects) within the radiofrequency environment. In an embodiment, the execution of the wavelet transform algorithm may identify time-localized frequency variations within the captured incident radiofrequency signal from the radiofrequency environment. Thus, in an embodiment, the signal feature extraction and preprocessing module 272 may first apply the Fourier transform algorithm to the captured incident radiofrequency signal to identify an overview of the captured incident radiofrequency signal's global frequency content and then execute a wavelet transform algorithm to identify time-localized frequency details within those identified frequencies within the captured incident radiofrequency signal.

It is appreciated that, in an embodiment, this data related to the AoA, AoD, ToF, frequency domain data for the captured incident radiofrequency signal, wireless data signal and interference components with varying frequency and time resolution of the captured radiofrequency signal may be described, generally, as feature characteristics of the captured incident radiofrequency signals that were partially coupled from the surface of the reconfigurable metasurface unit cell array 262. Along with deriving and identifying this data, the centralized metasurface hardware controller 264 may also execute computer-readable program code of a DRL algorithm 283. Execution of the DRL algorithm 283 allows the centralized metasurface hardware controller 264 to effectively manage each of the metasurface embedded microcontrollers 274-1, 274-2 associated with each of the metasurface unit cell subgroups 276-1, 276-2 to manage workloads among the metasurface embedded microcontrollers 274-1, 274-2 for distribution and adjustments of the resulting filtered offset radiofrequency signal at each metasurface unit cell subgroups 276-1, 276-2. The execution of the DRL algorithm 283 operates to coordinate and manage metasurface embedded microcontrollers 274-1, 274-2 for phase-shift and amplitude adjustments via attenuator circuits to compose a reflected radiofrequency signal with beamforming directionality, amplitude gain of desired radiofrequency signal components, and suppression of interference components.

As described herein, the feature characteristics of the incident radiofrequency signals (e.g., AoA, AoD, ToF, frequency domain data, signal components with varying frequency and time resolution, etc.) are derived by the centralized metasurface hardware controller 264 executing machine readable code instructions of the signal feature extraction and preprocessing module 272, this data is transmitted to a metasurface NPU 280. The metasurface NPU 280 may be part of the centralized metasurface hardware controller 264 or a separate hardware processing resource in various embodiments. The metasurface NPU 280 may be responsible for executing machine readable code instructions of a cGAN algorithm 282. The cGAN algorithm 282 may identify various types of interference and actively filter out unwanted interference from the captured incident radiofrequency signals by predicting and removing spurious interference portions and canceling ongoing, consistent interference of the captured incident radiofrequency signal in real-time. In an embodiment, the cGAN algorithm 282 may, through the use of a plurality of neural networks, generate a filtered offset radiofrequency signal that, when combined with the incident radiofrequency signals, causes the reflected radiofrequency signal having desirable wireless communication radiofrequency signal portions to be amplified at the reconfigurable metasurface unit cell array 262 and directed towards a receiving wireless device. Further, the cGAN algorithm 282 may, through the use of a plurality of neural networks, generate a filtered offset radiofrequency signal that, when combined with the incident radiofrequency signals, causes the reflected radiofrequency signal to have the unwanted distortion components in the incident radiofrequency signal to be muted or suppressed in the reflected radiofrequency signal from the reconfigurable metasurface unit cell array 262.

After the cGAN algorithm 282 has generated the filtered offset radiofrequency signal, the filtered offset radiofrequency signal may be transmitted to the centralized metasurface hardware controller 264. The metasurface hardware controller 264 may execute code instructions of the DRL algorithm 283 to manage distribution to and to relay the filtered offset radiofrequency signal to each of the metasurface embedded microcontrollers 274-1, 274-2 associated with and controlling the operation of each of the metasurface unit cell subgroups 276-1, 276-2. Each of the metasurface embedded microcontroller 274-1, 274-2 may be responsible for local processing of the filtered offset radiofrequency signal and may be directed how to process the filtered offset radiofrequency signal by the centralized metasurface hardware controller 264 executing machine readable code instructions of the DRL algorithm 283 to manage and partition distribution of the commands across the plurality of metasurface unit cell subgroups 276-1, 276-2. Thus, in an embodiment, the centralized metasurface hardware controller 264 may direct correction parameters to be applied to the filtered offset radiofrequency signal received by each of the metasurface embedded microcontroller 274-1, 274-2 may vary from one metasurface embedded microcontroller 274-1, 274-2 to another for cohesive generation of a reflected radiofrequency signal with increased wireless communication radiofrequency signal gain and directionality while suppressing interference components across the reconfigurable metasurface unit cell array 262. For example, each of the metasurface embedded microcontrollers 274-1, 274-2 may be provided with high-level signal correction data to be applied to the filtered offset radiofrequency signal at each metasurface unit cell subgroups 276-1, 276-2 thereby allowing each metasurface embedded microcontroller 274-1, 274-2 to interact with an attenuator circuit 275-1, 275-2 and tunable delay circuit 277-1, 277-2 in order to concurrently execute interference cancellation, beamforming/beamsteering, and amplitude gain of desirable components in the reflected radiofrequency signal at the reconfigurable metasurface unit cell array 262 as described herein.

When the metasurface embedded microcontrollers 274-1, 274-2 have applied the appropriate attenuation and phase shifting of the filtered offset radiofrequency signal across the plurality of metasurface unit cell subgroups 276-1, 276-2, metasurface embedded microcontrollers 274-1, 274-2 may cause the filtered offset radiofrequency signal to be sent to the RF/EM circuit network for the RF/EM circuit network to reintroduce that filtered offset radiofrequency signal into the reconfigurable metasurface unit cell array 262 across each of those respective metasurface unit cell subgroups 276-1, 276-2. This is coordinated by the centralized metasurface hardware microcontroller 264 executing the DRL algorithm 283 so that the filtered offset radiofrequency signal can interact with the original incident radiofrequency signals to generate a reflected radiofrequency signal with the directionality lobes toward a receiving wireless device with amplitude gain of the reflected radiofrequency signal components for wireless communication while interference components are suppressed. Thus, if the filtered offset radiofrequency signal is properly phase-aligned for cancellation, the filtered offset radiofrequency signal combines with unwanted interference components of the original incident radiofrequency signals thereby causing destructive interference and removing unwanted interference in the reflected radiofrequency signal across the metasurface unit cell subgroups 276-1, 276-2. Additionally, where the filtered offset radiofrequency signal is phase-aligned to reinforce the desired signal, it constructively interferes with the original incident radiofrequency signals thereby enhancing gain in the desired direction increasing the EM radiofrequency signal lobe of the reflected radiofrequency signal across the metasurface unit cell subgroups 276-1, 276-2. Indeed, by operation of the metasurface embedded microcontrollers 274-1, 274-2 and centralized metasurface hardware controller 264 and by tuning the phase shifts across metasurface unit cells 278-1, 278-2, 278-3, 278-4, the reconfigurable metasurface unit cell array 262 steers the reflected radiofrequency signal lobe toward the intended receiver device (e.g., information handling systems 200-1, 200-2, 200-3, AP 244, and 246) while mitigating interference components in the original incident radiofrequency signal. This improves signal clarity, quality, and strength and increases data transmission efficiency within the wireless network 242 at the reconfigurable metasurface unit cell array 262.

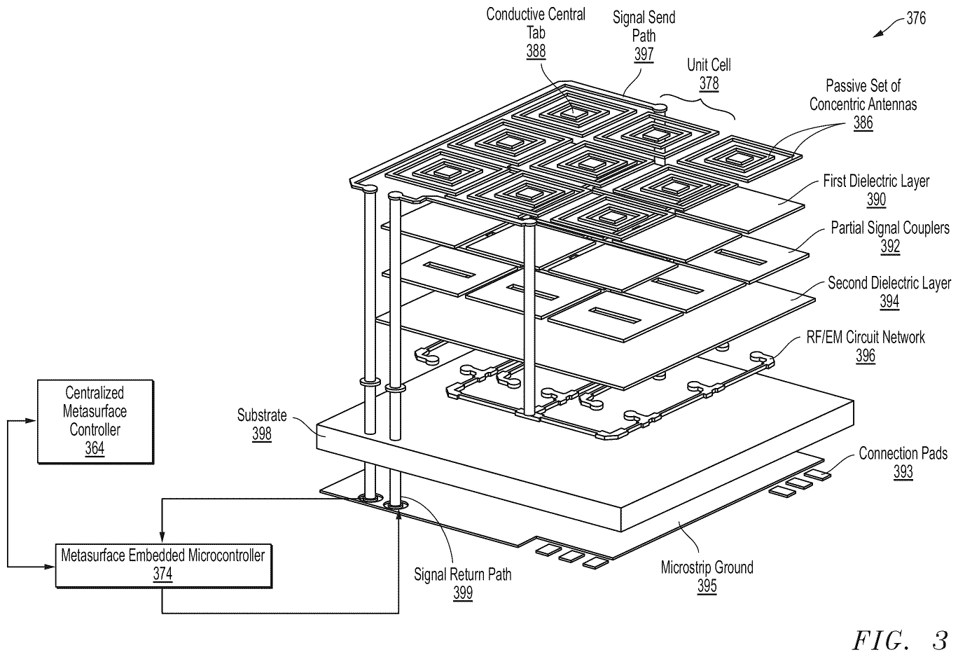

FIG. 3 is an exploded perspective view graphic diagram showing one of a plurality of metasurface unit cell subgroups 376 of metasurface unit cells 378 of a reconfigurable metasurface unit cell array according to an embodiment of the present disclosure. In an embodiment, the reconfigurable metasurface unit cell array includes a plurality of metasurface unit cells 378 having resonating structures formed on a dielectric substrate 398 shown in FIG. 3. It is appreciated, however, that a subgroup 376 of the reconfigurable metasurface unit cell array may include more or fewer than the number of metasurface unit cells 378 shown in FIG. 3. In an embodiment, the reconfigurable metasurface unit cell array may include an array of metasurface unit cells 378 arranged in rows and columns within the metasurface unit cell subgroup 376. In one example embodiment, the array of metasurface unit cells 378 may be formed into a nine-by-nine array of metasurface unit cells 378 in a metasurface unit cell subgroup 376. It is appreciated, however, that any arrangement and any number of metasurface unit cells 378 may be used to form the reconfigurable metasurface unit cell array or its subgroups described herein. In one embodiment, the metasurface unit cell subgroup 376 may include nine metasurface unit cells 378 with the metasurface unit cell subgroup 376 being operatively coupled to a metasurface embedded microcontroller 374 that controls the operation of the metasurface unit cell subgroup 376 and, in an embodiment, each metasurface unit cell 378 within its subgroup individually. In an embodiment, the metasurface embedded microcontroller 374 may be directed by the operation of the centralized metasurface hardware controller 364 that manages workload distribution to this metasurface embedded microcontroller 374 as well as a plurality of other metasurface embedded microcontrollers across the reconfigurable metasurface unit cell array.

It is appreciated that although FIG. 3 shows a single metasurface unit cell subgroup 376 with its respective metasurface embedded microcontroller 374, the present specification contemplates that any number more than the single metasurface unit cell subgroup 376 may be formed into the reconfigurable metasurface unit cell array. In one example embodiment, the reconfigurable metasurface unit cell array may be formed by arranging a plurality of metasurface unit cell subgroups 376 in columns and rows of in, for example, a six-by-six reconfigurable metasurface unit cell array.

Each of the metasurface unit cells 378 may include resonating structures formed on a dielectric substrate 398 sized and spaced for reflecting radiofrequency signals of particular wavelengths from the surface of the reconfigurable metasurface unit cell array. In an embodiment, the resonating structures are passive concentric resonating antennas 386 that are conductive and formed on the dielectric substrate 398 to resonate with the wavelength of incident EM waves for radiofrequency signals propagated from an antenna source within the radiofrequency environment. These radiofrequency signal may be propagated from an antenna of an information handling system, AP, base station, and other wireless network device within the radiofrequency environment within range of the reconfigurable metasurface unit cell array. The metasurface unit cells 378 may include a conductive fixed tab 388 within the concentric antennas formed on the dielectric substrate 398 in an embodiment. Further, while specific concentric antennas are discussed in embodiments herein (e.g., square concentric antennas), any shape of concentric antennas (e.g., round or another geometric shape) for the passive portions of the metasurface unit cells 378 may be used. These passive concentric resonating antennas 386 of the metasurface unit cells 378 may receive those incident radiofrequency signals and transfer the EM wave resonance through a partial signal coupler 392 and to an RF/EM circuit network 396 placed below the passive set of concentric antennas 386 of each metasurface unit cell 378 to capture partially coupled samples of the incident radiofrequency signal. These partially coupled samples may be referred to as captured radiofrequency signals or captured incident radiofrequency signals in embodiments herein. The RF/EM circuit network 396 of each metasurface unit cell 378 act as a coupler to capture the captured incident radiofrequency signals for the processing units, such as the metasurface embedded controller 374 and the centralized metasurface controller 364 that manipulate the captured EM wave energy of the captured incident radiofrequency signal from the passive set of concentric antennas 386, conductive central tab 388, and partial signal couplers 392 as described herein.

The metasurface unit cell subgroup 376 may also include a first dielectric layer 390 that is placed between the passive set of concentric antennas 386 and the partial signal coupler 392. As second dielectric layer 394 may also be placed between the partial signal coupler 392 and RF/EM circuit network 396. Each of these dielectric layers 390, 394 may be made of a polymer, a plastic, a ceramic, a ceramic oxide, composite materials such as printed circuit board (PCB) metasurfaces, and the like to prevent electrical coupling between the passive set of concentric antennas 386, the partial signal coupler 392, and the RF/EM circuit network 396. In some embodiments, the first dielectric layer 390 and second dielectric layer 394 may be considered as part of the dielectric substrate 398. In other embodiments, the first dielectric layer 390 and second dielectric layer 394 may be additional layers formed in addition to forming the RF/EM circuit network 396, the partial signal coupler 392, and the resonant passive set of concentric antennas 386 over the dielectric substrate 398 for each metasurface unit cell 378 in the subgroup 376.

In an embodiment, the metasurface unit cells 378 may be formed onto a dielectric substrate 398 that has a microstrip ground layer 395 formed below the substrate 398 for the metasurface embedded microcontroller 374 to be operatively coupled to the metasurface unit cell subgroup 376 and its RF/EM circuit network 396 or other controllable aspects via one or more connection pads 393. As described herein, the RF/EM circuit network 396 may transmit the captured incident radiofrequency signal to the metasurface embedded microcontroller 374 via, in an example embodiment, a signal send path 397. When the generated filtered offset radiofrequency signal from the metasurface embedded microcontroller 374 and the centralized metasurface hardware controller 364 in embodiments herein is to be applied at the RF/EM circuit network 396 and back to the passive set of concentric antennas 386, the metasurface embedded microcontroller 374 may pass this filtered offset radiofrequency signal via a signal return path 399.

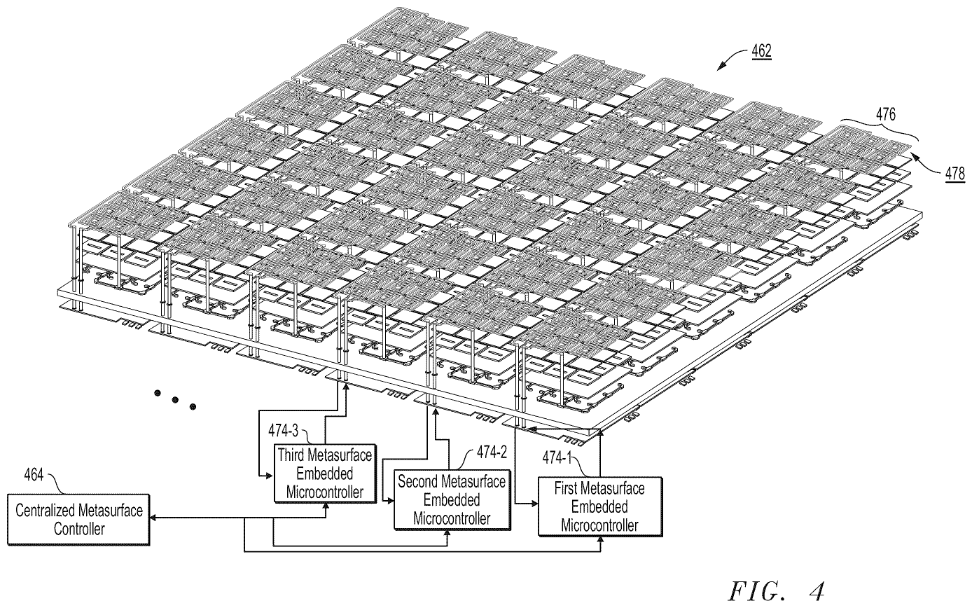

FIG. 4 is an exploded perspective view graphic diagram showing a reconfigurable metasurface unit cell array 462 with a plurality of metasurface unit cells 478 grouped into metasurface unit cell subgroups 476 each operatively coupled to a metasurface embedded microcontroller 474-1, 474-2, 474-3 according to an embodiment of the present disclosure. As described in connection with FIG. 3, the reconfigurable metasurface unit cell array 462 may include a plurality of metasurface unit cell subgroups 476 arranged in rows and columns to form the reconfigurable metasurface unit cell array 462. In one example embodiment, shown in FIG. 4, for example, the reconfigurable metasurface unit cell array 462 comprises thirty-six individual metasurface unit cell subgroups 476 arranged in a six-by-six reconfigurable metasurface unit cell array 462 of metasurface unit cell subgroups 476.

As described herein, each of the metasurface embedded microcontrollers 474-1, 474-2, 474-3 are operatively coupled to the centralized metasurface hardware controller 464 for the reconfigurable metasurface unit cell array 476. During operation, the centralized metasurface hardware controller 464 may receive captured incident radiofrequency signals from the metasurface unit cells and derive feature characteristic data from those samples of the captured incident radiofrequency signals that are incident to the reconfigurable metasurface unit cell array 462. The partial signal coupler of each of the metasurface unit cells 478 captures a portion of the incident radiofrequency signals received at the passive concentric resonating antennas and diverts or couples this small portion or sample of the incident radiofrequency signals to the RF/EM circuit network formed in each metasurface unit cell 478 as described in connection with FIG. 3 for example. In an embodiment, the portion or sample of the incident radiofrequency signals may retain all phase, amplitude, frequency, and polarization information of each of the incident radiofrequency signals, including interference and distortion, that are incident to the reconfigurable metasurface unit cell array 462. The RF/EM circuit network placed below each of the metasurface unit cells 478 may pass the partial signal received by the partial signal coupler to the centralized metasurface hardware controller 464, via each of the metasurface embedded microcontrollers 474-1, 474-2, 474-3, so that the centralized metasurface hardware controller 464 can derive the AoA data and other feature characteristic data related to the captured incident radiofrequency signals via execution of machine readable code instructions of a signal feature extraction and preprocessing module according to embodiments herein.

Indeed, because the metasurface unit cells 478 and/or metasurface unit cell subgroups 476 have known sizes and are spatially separated from each other by known distances, the incident radiofrequency signals will reach each of the metasurface unit cells 478 and/or metasurface unit cell subgroups 476 at different times creating phase differences between the detected partial signals received at the RF/EM circuit network. Using this timing data, known dimensions and distances, and known wavelengths, the AoA data may be computed by the centralized metasurface hardware controller 464 executing machine readable code instructions of a signal feature extraction and preprocessing module. Similarly, the centralized metasurface hardware controller 464 may calculate the AoD using, for example, a MUSIC algorithm, or an ESPIRIT algorithm, from the AoA or estimate the AoD for the return path to the transmitting wireless network device. Also, based on an embedded signal of the captured incident radiofrequency signals, the metasurface hardware controller 464 may also determine the ToF data of the incident radiofrequency signals. Additionally, by operation of the metasurface hardware controller 464 executing machine readable code instructions of a signal feature extraction and preprocessing module, the wireless communication components and the spurious or consistent interference components of the captured incident radiofrequency signal may be identified. The execution of machine readable code instructions of a signal feature extraction and preprocessing module may then generate a filtered offset radiofrequency signal to be returned to each of the metasurface embedded microcontrollers 474-1, 474-2, 474-3 for attenuation and phase shifting pursuant to instructions from the centralized metasurface hardware controller 464 as described various embodiments herein.

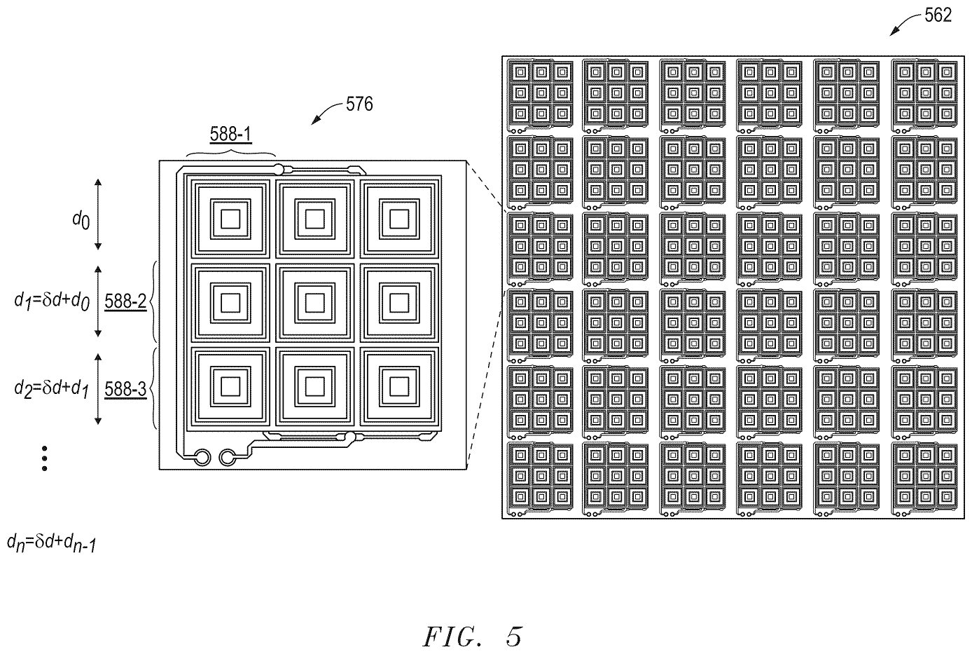

FIG. 5 is a top view graphic diagram showing an exploded view of one of a plurality of metasurface unit cell subgroups 576 forming a portion of a reconfigurable metasurface unit cell array 562 used to detect AoA of incident radiofrequency signals within the wireless network and determine an appropriate AoD for those wireless transmission reflected off of the reconfigurable metasurface unit cell array 562 according to an embodiment of the present disclosure. As described herein, the metasurface unit cell subgroups 576 may be one of a plurality of metasurface unit cell subgroups 576 that form a complete metasurface unit cell array 562. In an embodiment, each of the metasurface unit cell subgroups 576 may include those elements and circuits described in connection with FIGS. 1 through 3.

During operation, each of the metasurface unit cell subgroups 576 of the metasurface unit cell array 562 may interact with a plurality of wireless transmission radiofrequency signals (e.g., EM waves) of particular radiofrequency wavelengths from a plurality of network devices located within and operatively coupled to the wireless network in the radiofrequency environment. These wireless transmissions may include high frequency transmissions that may be boosted and beamformed by the operation of the reconfigurable metasurface unit cell array 562 such that they may be extended by the reconfigurable metasurface unit cell array 562 and relayed to the appropriate receiving device within the wireless network. In an embodiment, some of these wireless transmission radiofrequency signals may be boosted by reflection off of the reconfigurable metasurface unit cell array 562 such that the effective range of the radiofrequency signal transmission is increased.

In order to determine the AoA data, the AoD data, and ToF data of each incident radiofrequency signal received at the reconfigurable metasurface unit cell array 562, the centralized metasurface hardware controller may be provided with appropriate differential delay data from each of the plurality of metasurface unit cells 588-1, 588-2, 588-3 within each of the metasurface unit cell subgroups 576 of the reconfigurable metasurface unit cell array 562. The plurality of metasurface unit cells 588-1, 588-2, 588-3 have known spacing and size dimensions within each of the metasurface unit cell subgroups 576 in embodiments herein.

For example, because the incident radiofrequency signals may interact with resonating structures on a first metasurface unit cell 588-1, a difference in time of arrival may be detected at a second metasurface unit cell 588-2, and a third metasurface unit cell 588-3 and reported to the centralized metasurface hardware controller. The time of arrival of the RF transmission at the first metasurface unit cell 588-1 may be set at a first differential time “d₀” in an embodiment. Thus, the first differential delay “d₁” t the second metasurface unit cell 588-2 may be computed by adding the first differential time first differential time “d₀” to a detect time difference “δd” between the arrival of the RF transmission at the first metasurface unit cell 588-1 and the arrival of the RF transmission of the second metasurface unit cell 588-2. This may be repeated for each metasurface unit cell 588-1, 588-2, 588-3 such that a differential delay at any given unit cell “dₙ” may be defined by the following equation: dₙ−δd+dₙ₋₁. This calculation, in an example embodiment, may be conducted by the metasurface hardware controller with known spacing and dimensions of the metasurface unit cells 588-1, 588-2, 588-3 as well as the wavelength of the incident radiofrequency signal to arrive at an AoA for each of the plurality of RF transmissions detected at the surface of the entire metasurface unit cell array 562. Additionally, the AoD of the RF transmission from the RF transmission-originating network device may also be calculated by the metasurface hardware controller to determine a physical direction and/or location of the RF transmission-originating network device within the wireless network. In other embodiments, one or more algorithms may be executed by the centralized metasurface hardware controller to determine the AoD of the target wireless network device based on the AoA data according to various embodiments herein. This AoA data and AoD data, along with ToF data, may be passed onto the metasurface NPU described in connection with FIGS. 1 and 2 for further processing as described herein.

It is appreciated that, in an example embodiment, this difference in time of arrival of the incident radiofrequency signals may be detected among the individual metasurface unit cell subgroups 576 in a metasurface unit cell subgroup 576 by metasurface unit cell subgroup 576 manner. Thus, the example showing the calculation of the AoA data using the plurality of metasurface unit cells 588-1, 588-2, 588-3 may instead, or additionally, be completed using the time or arrival at a given metasurface unit cell subgroup 576 relative to another metasurface unit cell subgroup 576.

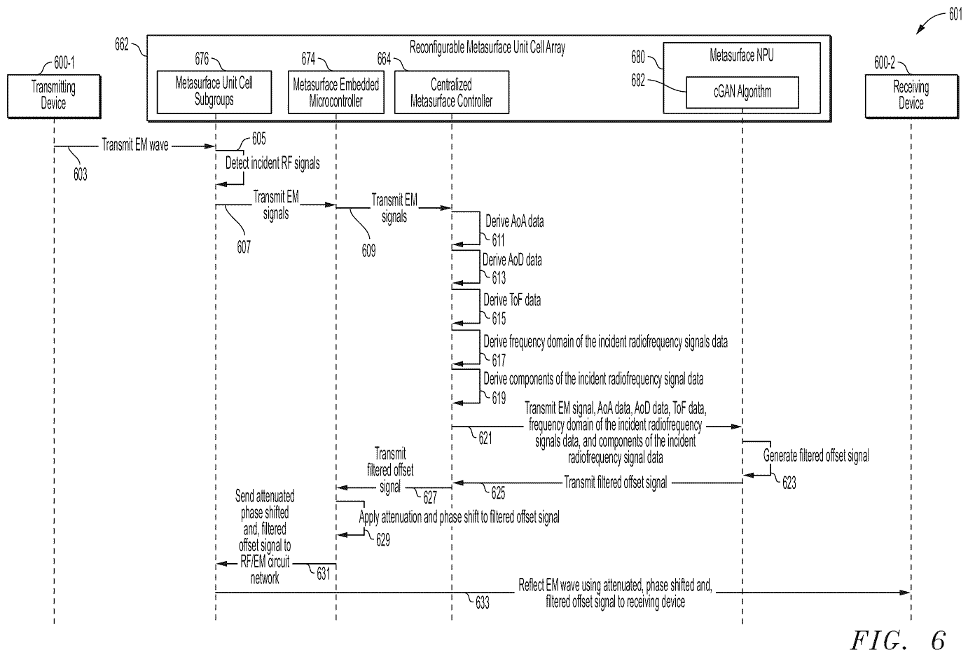

FIG. 6 is a swimlane diagram showing a method of mitigating radiofrequency signal interference in a radiofrequency environment at a reconfigurable metasurface unit cell array according to an embodiment of the present disclosure. FIG. 6 shows a transmitting device 600-1 and a receiving device 600-2 that are wirelessly communicating with each other in a radiofrequency environment. It is appreciated, however, that the transmitting device 600-1 and receiving device 600-2 may engage in both transmissions and receptions of wireless communications thereby switching roles as described in connection with FIG. 6.

At line 603, the method 601 may include the transmitting device 600-1 sending a wireless communication in the form of an EM wave for a radiofrequency signal to towards the receiving device 600-2. Because smaller wavelength radiofrequencies are more frequently being used within the wireless networks to transmit larger amounts of data, issues arise with these shorter wavelength RF transmissions having a limited range especially through objects. Additionally, these shorter wavelength RF transmissions degrade over long distances. In an embodiment, the reconfigurable metasurface unit cell array 662 may be many of a plurality of reconfigurable metasurface unit cell arrays 662 placed within a given area of the wireless network in order to facilitate the relay of these types of wireless transmissions.

The transmitted EM wave of the radiofrequency signal at line 603 is received at one or more metasurface unit cell subgroups 676 of the reconfigurable metasurface unit cell array 662. As described herein, the RF/EM circuit network of each of the metasurface unit cells within the metasurface unit cell subgroups 676 may detect the EM waves of the incident radiofrequency signals incident to the surface of the reconfigurable metasurface unit cell array 662. In an embodiment, the RF/EM circuit networks act as wireless coupler to the processing units that manipulate the captured EM wave energy, by capturing a portion of the incident radiofrequency signal via wirelessly coupling the radiofrequency signals from the passive concentric resonating antennas and partial signal couplers. The RF/EM circuit network sends the captured incident radiofrequency signals, at line 607, to the metasurface embedded microcontroller 674 for a metasurface unit cell subgroup. At line 609, each of the metasurface embedded microcontrollers 674 associated with each of the metasurface unit cell subgroups 676 may transmit their respective captured EM signals of the radiofrequency signal incident to the reconfigurable metasurface unit cell array 662 to the centralized metasurface hardware controller 664 for additional processing.

During operation, the centralized metasurface hardware controller 664 may receive and derive data describing those wireless transmissions within the wireless network from those captured incident radiofrequency signal partial coupling samples from the radiofrequency signal incident to the reconfigurable metasurface unit cell array 662. In an embodiment, during operation of the reconfigurable metasurface unit cell array 662, the partial signal coupler and RF/EM circuit network of the metasurface unit cell subgroups 676 may be used by the centralized metasurface hardware controller 664 to determine AoA data of the incident radiofrequency signals as received across a plurality of metasurface unit cells with known dimension and spacing in the metasurface unit cell subgroups 676. In this embodiment, the centralized metasurface hardware controller 664 may use the partial signals received from each of the plurality of metasurface unit cells and/or a plurality of metasurface unit cell subgroups 676. Because the metasurface unit cells and/or metasurface unit cell subgroups 676 are spatially separated from each other with known spacing and having known dimension, the incident radiofrequency signals will reach each of the metasurface unit cells and/or metasurface unit cell subgroups 676 at different times creating phase differences between the detected partial captured incident radiofrequency signals received at the RF/EM circuit network. Using this data, AoA data may be computed by the centralized metasurface hardware controller 664 as described herein.

Thus, at line 607, the EM signals of the partial coupling samples of the captured incident radiofrequency signal may be transmitted to each metasurface embedded microcontroller 674 associated with each of the metasurface unit cell subgroups 676. Those EM signals of the partial coupling samples of the captured incident radiofrequency signal received at each of the metasurface embedded microcontrollers 674 may be independently transmitted, at line 609, to the centralized metasurface hardware controller 664 as described. With this independent reporting of the EM signals of the partial coupling samples of the captured incident radiofrequency signal from each of the metasurface embedded microcontrollers 674, the centralized metasurface hardware controller 664 may calculate or otherwise derive the AoA data at line 611.

Similarly, the centralized metasurface hardware controller 664 may, at line 613, executes machine readable code instructions of a signal feature extraction and preprocessing module to calculate the AoD using, for example, a MUSIC algorithm, an estimation of a ESPIRIT algorithm, or another algorithm for estimation of the AoD from the calculated AoA for wireless devices in the radiofrequency environment. Also, based on an embedded signal of the incident radiofrequency signals, the centralized metasurface hardware controller 264 may, at line 615, determine the ToF data of the incident radiofrequency signals as described herein.

As the centralized metasurface hardware controller 664 calculates the AoA data, the AoD data, and the ToF data the centralized metasurface hardware controller 664 may also further execute machine readable code instructions of a signal feature extraction and preprocessing module. The execution of the signal feature extraction and preprocessing module 672 may, at line 617, cause the centralized metasurface hardware controller 664 to identify the frequency domain of the captured incident radiofrequency signals (using, for example, a Fourier transform algorithm) into a time domain. Further, the centralized metasurface hardware controller executes machine readable code instructions of the signal feature extraction and preprocessing module to determine, at line 619, components, such as desired wireless communication radiofrequency components and various interference components, of the captured incident radiofrequency signal with varying frequency and time resolution as described herein.

This derived and calculated data may be then transmitted to the cGAN algorithm 682 being executed by a metasurface NPU 680 at line 621. Metasurface NPU 680 may be part of the centralized metasurface hardware controller 664 in some embodiments or may be a separate hardware processing resource at the centralized processing of the reconfigurable metasurface unit cell array 662 in various embodiments. As described herein, the AoA data, the AoD data, the ToF data, the frequency domain of the incident radiofrequency signals data, and the wireless communication and interference components of the incident radiofrequency signal data are feature characteristics of the captured incident radiofrequency signals that are used as input to the cGAN algorithm 682.

Thus, at line 623, the cGAN algorithm 682 may generate a filtered offset radiofrequency signal as described herein. Again, the metasurface NPU 680 may be responsible for executing machine readable code instructions of a cGAN algorithm 682. The cGAN algorithm 682 may actively filter out unwanted interference components, both spurious or consistent, from the captured incident radiofrequency signals by predicting and removing spurious portions of the signal or canceling/filtering ongoing, consistent interference components in real-time. In an embodiment, the cGAN algorithm 682 may, through the use of a plurality of neural networks, generate a filtered offset radiofrequency signal that, when combining the filtered offset radiofrequency signal with the incident radiofrequency signals across the plurality of metasurface unit cell subgroups 676, causes the reflected radiofrequency signal to be amplified for desired components such as wireless communication radiofrequency signal components at the reconfigurable metasurface unit cell array 662 while the unwanted distortion or interference signal components are muted.

In an embodiment, after the cGAN algorithm 682 has generated the filtered offset radiofrequency signal, the filtered offset radiofrequency signal may be transmitted, at line 625 to the centralized metasurface hardware controller 664 for the centralized metasurface hardware controller 664 to relay the filtered offset radiofrequency signal to each of the metasurface embedded microcontrollers 674 associated with and controlling the operations across each of the metasurface unit cell subgroups 676 at line 327. Each of the metasurface embedded microcontrollers 674 may be responsible for local processing of the filtered offset radiofrequency signal and may be directed how to process the filtered offset radiofrequency signal by the centralized metasurface hardware controller 664 for its corresponding metasurface unit cell subgroup 676.

Thus, in an embodiment, the centralized metasurface hardware controller 664, with the filtered offset radiofrequency signal, may transmit correction parameters that are to be applied to the filtered offset radiofrequency signal received by each of the metasurface embedded microcontrollers 674 for adjustments to phase shift and amplitude across the plurality of metasurface unit cell subgroups 676. In an embodiment, these correction parameters may vary from one metasurface embedded microcontroller 674 to another. For example, each of the metasurface embedded microcontrollers 674 may be provided with high-level signal correction data to be applied to the filtered offset radiofrequency signal thereby allowing each metasurface embedded microcontroller 674 to interact with an attenuator circuit and tunable delay circuit in order to concurrently execute interference cancellation, beamforming/beamsteering, and amplitude gain adjustment at the reconfigurable metasurface unit cell array 662 as described herein. Thus, at line 629, each of the metasurface embedded microcontrollers 674 may apply these attenuation and phase shift parameters to the filtered offset radiofrequency signal to each corresponding metasurface unit cell subgroup 676 across the reconfigurable metasurface unit cell array 662. In this way, the reflected radiofrequency signal from the incident radiofrequency signal may be beamformed directionally towards a receiving wireless device and have increased gain of desirable components of the radiofrequency signal while interference components may be mitigated.

When the metasurface embedded microcontrollers 674 have applied the appropriate attenuation and phase shifting of the filtered offset radiofrequency signal, the metasurface embedded microcontrollers 674 may cause the attenuated, phase shifted, and filtered offset radiofrequency signal to be sent to the RF/EM circuit network at line 631. The attenuated, phase shifted, and filtered offset radiofrequency signal may be, with the RF/EM circuit network, reintroduce into the reconfigurable metasurface unit cell array 662 across the plurality of metasurface unit cell subgroups 676 so that the filtered offset radiofrequency signal can interact with the original incident radiofrequency signals. Thus, at line 633 the EM wave of the original incident radiofrequency signal is combined with the attenuated, phase shifted, and filtered offset radiofrequency signal to be reflected off of the surface of the reconfigurable metasurface unit cell array 662 with directionality, increased gain of desirable components and suppressed interference in the direction of the receiving device 600-2. Again, if the filtered offset radiofrequency signal is properly phase-aligned for cancellation, the filtered offset radiofrequency signal combines with unwanted interference components of the original incident radiofrequency signals thereby causing destructive interference and removing unwanted interference. Additionally, where the filtered offset radiofrequency signal is phase-aligned to reinforce the desired signal, it constructively interferes with the original incident radiofrequency signals thereby enhancing gain in the desired direction increasing the EM radiofrequency signal lobe of the reflected EM radiofrequency signal. Indeed, by operation of the centralized metasurface embedded microcontrollers 674 and metasurface hardware controller 664 and by tuning the phase shifts across metasurface unit cells, the reconfigurable metasurface unit cell array 662 steers the EM radiofrequency signal lobe toward the intended receiver device 600-2 while reducing interference. This improves signal clarity, quality, and strength and increases data transmission efficiency within the wireless network at the reconfigurable metasurface unit cell array 662.

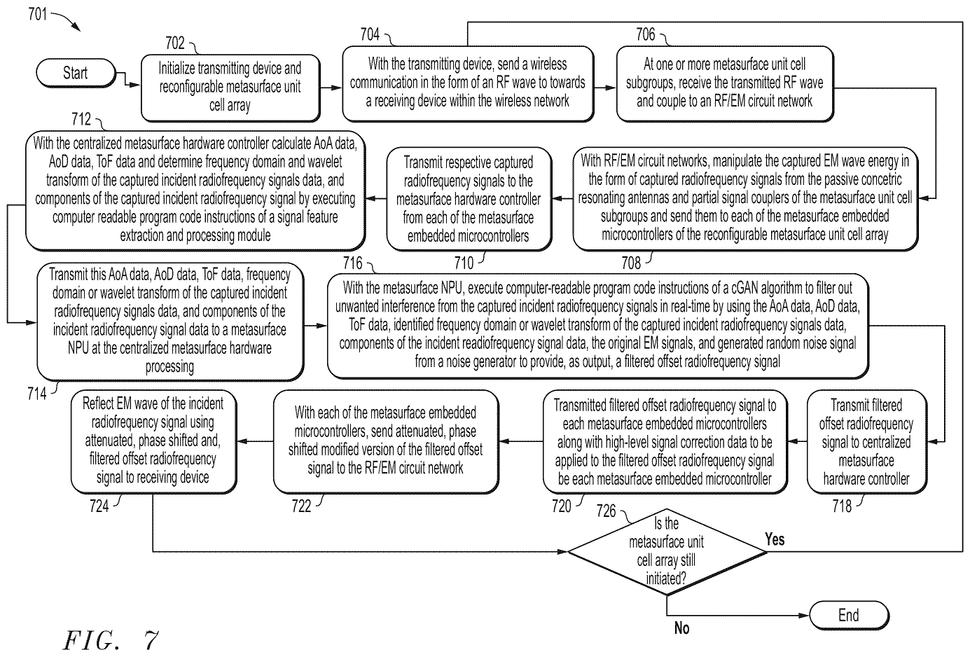

FIG. 7 is a flow diagram of a method 701 of mitigating radiofrequency signal interference in a radiofrequency environment at a reconfigurable metasurface unit cell array according to another embodiment of the present disclosure. The metasurface unit cell array used in this method 701 may be similar to those reconfigurable metasurface unit cell arrays described in connection with, for example, FIGS. 1 through 5. The reconfigurable metasurface unit cell array may include a plurality of metasurface unit cells formed into a plurality of metasurface unit cell subgroups that are individually controlled using a metasurface PMU or other power source, embedded metasurface microcontrollers for each subgroup, a centralized metasurface hardware controller, and other components as described herein.

At block 702, the method 701 may include initiating the transmitting wireless device, such as one or more wireless information handling systems, and the reconfigurable metasurface unit cell array in a radiofrequency environment. In an embodiment, the transmitting device may be initiated by a user actuating a power button at the information handling system. Actuation of the power button initializes power to a hardware processor of the transmitting device. The user may initialize the reconfigurable metasurface unit cell array by coupling the reconfigurable metasurface unit cell array to a power source (e.g., metasurface PMU 178, FIG. 1), such as by actuating a button at the reconfigurable metasurface unit cell array. In an embodiment, the reconfigurable metasurface unit cell array may be placed at a location within a radiofrequency environment where wireless transmissions pursuant to wireless network operations may be reflected off of the surface of the reconfigurable metasurface unit cell array so that the radiofrequency signals of any given wireless transmission may be extended within the radiofrequency environment or that wireless transmissions may be reflected around objects such as walls within the radiofrequency environment.

At block 704, the method 701 may include the transmitting wireless device sending a wireless communication radiofrequency signal in the form of an RF wave to towards the receiving wireless device. Because smaller wavelength radiofrequencies are more frequently being used within wireless networks to transmit larger amounts of data, issues arise with these shorter wavelength RF transmissions having a limited range especially through objects. Additionally, these shorter wavelength, higher frequency RF transmissions degrade over long distances. In an embodiment, the reconfigurable metasurface unit cell array may be many of a plurality of reconfigurable metasurface unit cell arrays placed within a given radiofrequency environment for operation of one or more wireless networks in order to facilitate the relay of these type of radiofrequency signals of the wireless communication transmissions.

The transmitted EM wave of a radiofrequency signal may then, at block 706, be incident to or received at one or more metasurface unit cell subgroups of the reconfigurable metasurface unit cell array. As described herein, the RF/EM circuit network of each of the metasurface unit cells within the metasurface unit cell subgroups may detect and couple a portion these incident radiofrequency signals incident to the surface of the reconfigurable metasurface unit cell array, including wireless communication components and interference components of the radiofrequency signals. In an embodiment, the RF/EM circuit networks act as a coupler to capture the EM wave energy of these captured radiofrequency signals from the passive concentric resonating antennas and partial signal couplers of each metasurface unit cell.

At block 708, the RF/EM circuit networks provide these captured radiofrequency signals, with wireless communication and interference components included, to the processing units such as the embedded metasurface microcontroller for a subgroup and the centralized metasurface hardware controller for the reconfigurable metasurface unit cell array. These RF/EM circuit networks for each metasurface unit cell in a subgroup proceed to send these captured radiofrequency signals, at block 708, to each of the metasurface embedded microcontrollers of the reconfigurable metasurface unit cell array.

At block 710, each of the metasurface embedded microcontrollers associated with each of the metasurface unit cell subgroups may transmit their respective EM signals of the captured radiofrequency signal to the centralized metasurface hardware controller. As described herein, each of the metasurface unit cell subgroups have an associated metasurface embedded microcontroller that acts as an intermediate hardware processing device that sends, receives, and manipulates received data from the centralized metasurface hardware controller.

At block 712, the method 701 may further include executing machine readable code instructions of a signal feature extraction and processing module to calculate AoA data, AoD data, ToF data, frequency domain of the captured incident radiofrequency signals data, and identify and determine wireless communication and interference components of the captured incident radiofrequency signal data. In an embodiment, the centralized metasurface hardware controller may use the partial signals received from each of the plurality of metasurface unit cells and/or metasurface unit cell subgroups. Because the metasurface unit cells and/or metasurface unit cell subgroups are spatially separated from each other at known distances and of known dimension, the incident radiofrequency signals will reach each of the metasurface unit cells and/or metasurface unit cell subgroups at different times creating phase differences between the detected partial signals received at the RF/EM circuit network. Using this data, AoA data may be computed by the centralized metasurface hardware controller as described herein.

Similarly, the centralized metasurface hardware controller may calculate the AoD using, for example, a MUSIC algorithm, or an estimation of an ESPIRIT algorithm. It is contemplated that any number of algorithms may be used to determine the AoD from the AoA data for locations of particular wireless devices in a radiofrequency environment in embodiments of the present disclosure. Also, based on an embedded signal of the incident radiofrequency signals, the centralized metasurface hardware controller may also determine the ToF data of the incident radiofrequency signals.

In addition to the centralized metasurface hardware controller calculates the AoA data, the AoD data, and the ToF data, the centralized metasurface hardware controller may also execute further machine readable code instructions of a signal feature extraction and preprocessing module to determine feature characteristics of the captured incident radiofrequency signal. The execution of the signal feature extraction and preprocessing module may, in an example embodiment, causes the centralized metasurface hardware controller to identify a frequency domain version of the captured, incident radiofrequency signals (using, for example, a Fourier transform algorithm) for additional signal analysis. With this frequency domain version, the wireless communication and spurious or consistent interference components of the captured incident radiofrequency signal may be identified with their varying frequency and time resolution. It is appreciated that, in an embodiment, this data related to the AoA, AoD, ToF, frequency domain data, signal components with varying frequency and time resolution may be described, generally, as those feature characteristics of the captured, incident radiofrequency signals incident to the surface of the reconfigurable metasurface unit cell array.

At block 714, the method 701 also includes transmitting this AoA data, AoD data, ToF data frequency domain of the incident radiofrequency signals data, and components of the incident radiofrequency signal data to a metasurface NPU at the centralized metasurface processing. In some embodiments, the metasurface NPU is a portion of the centralized metasurface hardware controller. In other embodiments, the metasurface NPU may be an additional hardware processing resource working in conjunction with the centralized metasurface hardware controller. As described herein, this data is used as input to the cGAN algorithm executing at the metasurface NPU.

Thus, at block 716, the method 701 also includes the metasurface NPU executing machine readable code instructions of a cGAN algorithm. The cGAN algorithm may actively identify spurious or consistent interference and filter out unwanted interference from the captured incident radiofrequency signals by predicting and removing spurious portions of the signal and cancelling consistent interference in real-time. As described herein, the metasurface NPU may execute machine readable code instructions of the cGAN algorithm to filter out unwanted interference from the incident radiofrequency signals by predicting and removing spurious portions of the signal and canceling consistent interference portions in real-time by using the AoA data, AoD data, ToF data, frequency domain of the incident radiofrequency signals data, identified components of the incident radiofrequency signal data, the original EM signals, and a generated random noise signal from a noise generator as input and provide, as output, a filtered offset radiofrequency signal according to embodiments herein.

At block 718, the method 701 includes transmitting filtered offset radiofrequency signal to the centralized metasurface hardware controller. In an embodiment, centralized metasurface hardware controller may also execute computer-readable program code of a DRL algorithm. Execution of the DRL algorithm allows the centralized metasurface hardware controller to effectively manage each of the metasurface embedded microcontrollers associated with each of the metasurface unit cell subgroups thereby managing workloads distributed among the metasurface embedded microcontrollers to ensure scalability and low-latency feedback and data transmissions for manipulation of the filtered offset radiofrequency signal across the plurality of metasurface unit cells in the reconfigurable metasurface unit cell array. Thus, in an embodiment, the processing requirements during the operation of the reconfigurable metasurface unit cell array are distributed among a plurality of hardware processing devices for phase and amplitude adjustments across metasurface unit cell subsets. This provides for real-time evaluation of the incident radiofrequency signals and interference mitigation by the reconfigurable metasurface unit cell array during any given wireless transmission within the radiofrequency environment relayed by the reconfigurable metasurface unit cell array.

At block 720, the centralized metasurface hardware controller may send the filtered offset radiofrequency signal to each metasurface embedded microcontrollers along with high-level signal correction data to be applied to the filtered offset radiofrequency signal by each metasurface embedded microcontroller. For example, each of the metasurface embedded microcontrollers may be provided with high-level signal correction data to be applied to the filtered offset radiofrequency signal. With this high-level signal correction data, each metasurface embedded microcontroller manipulates the filtered offset radiofrequency signal via interaction with an attenuator circuit and tunable delay circuit in order to concurrently execute the interference cancellation, beamforming, and beamsteering at its metasurface unit cell subgroup across the reconfigurable metasurface unit cell array as described in embodiments herein.

At block 722, the method 701 further includes, with each metasurface embedded microcontroller, sending attenuated, phase shifted, and filtered offset radiofrequency signal to the RF/EM circuit network for each respective metasurface unit cell subgroup across the reconfigurable metasurface unit cell array. The attenuated, phase shifted, and filtered offset radiofrequency signal may be, with the RF/EM circuit network, reintroduced into concentric resonant antennas of the reconfigurable metasurface unit cell array so that the filtered offset radiofrequency signal can interact with the reflection of the original incident radiofrequency signals. As this occurs across plural metasurface unit cell subgroups across the reconfigurable metasurface unit cell array, real time beamforming may be achieved in the reflected radiofrequency signal as well as amplitude gain of desired components, such as a wireless communication radiofrequency signal component, increased via application of the attenuated, phase shifted, filtered offset radiofrequency signal. Further, real time reduction of interference components of the reflected radiofrequency signals may be achieved across the metasurface unit cell subgroups via application of the attenuated, phase shifted, and filtered offset radiofrequency signal to the reflected radiofrequency signals.

Thus, at block 724, the EM wave of the incident radiofrequency signal is reflected off of the surface of the reconfigurable metasurface unit cell array combined with the attenuated, phase shifted, filtered offset radiofrequency signal and the reflected radiofrequency signal continues onto the direction of the receiving wireless device in the radiofrequency environment with reduced interference and enhanced wireless communication radiofrequency signal component. Again, if the filtered offset radiofrequency signal is properly phase-aligned for cancellation, the filtered offset radiofrequency signal combines with unwanted interference components of the original incident radiofrequency signals thereby causing destructive interference and removing unwanted interference. Additionally, where the filtered offset radiofrequency signal is phase-aligned to reinforce the desired signal, it constructively interferes with the original incident radiofrequency signals thereby enhancing gain in the desired components of the radiofrequency signal in a direction increasing the EM radiofrequency signal lobe of the reflected radiofrequency signal. Indeed, by operation of the metasurface embedded microcontrollers and centralized metasurface hardware controller and by tuning the phase shifts across metasurface unit cells, the reconfigurable metasurface unit cell array steers the EM radiofrequency signal lobe toward the intended receiver device in the radiofrequency environment. This improves signal clarity, quality, and strength and increases data transmission efficiency of the wireless network within the radiofrequency environment at the reconfigurable metasurface unit cell array.

At block 726, the method 701 includes determining if the metasurface unit cell array and transmitting device are still initiated. Where the metasurface unit cell array and transmitting device are still initiated, the method 701 proceeds to block 704 with the transmitting device continuing to transmit data and the metasurface unit cell array interacting with those transmissions. Where the metasurface unit cell array and transmitting device are no longer initiated, the method 701 may end here.

The processes or steps and aspects of the operation of the embodiments, such as FIGS. 6 and 7, herein and discussed herein need not be performed in any given or specified order. It is contemplated that additional blocks, steps, or functions may be added, some blocks, steps or functions may not be performed, blocks, steps, or functions may occur contemporaneously, and blocks, steps, or functions from one flow diagram may be performed within another flow diagram.

Devices, modules, resources, or programs that are in communication with one another need not be in continuous communication with each other, unless expressly specified otherwise. In addition, devices, modules, resources, or programs that are in communication with one another can communicate directly or indirectly through one or more intermediaries.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

The subject matter described herein is to be considered illustrative, and not restrictive, and the appended claims are intended to cover any and all such modifications, enhancements, and other embodiments that fall within the scope of the present invention. Thus, to the maximum extent allowed by law, the scope of the present invention is to be determined by the broadest permissible interpretation of the following claims and their equivalents and shall not be restricted or limited by the foregoing detailed description.

What is claimed is:

1. A reconfigurable metasurface unit cell array comprising:
a centralized metasurface hardware controller, a metasurface memory device, and a metasurface power management unit (PMU) to provide power to the centralized metasurface hardware controller and metasurface memory device;
the reconfigurable metasurface unit cell array comprising a plurality of reconfigurable unit cells to reflect a reflected radiofrequency signal from an incident radiofrequency signal from a radiofrequency environment at the surface of the reconfigurable metasurface unit cell array;
the plurality of metasurface unit cells coupling, via a partial signal coupler, a portion of the incident radiofrequency signal into a radiofrequency/electromagnetic (RF/EM) circuit network below resonating antennas of each metasurface unit cell to transmit a captured incident radiofrequency signal to the centralized metasurface hardware controller;
the centralized metasurface hardware controller to execute machine readable code instructions of a signal feature extraction and preprocessing module to identify feature characteristics data, including identifying a wireless communication component and interference components of the captured incident radiofrequency signal;
a hardware metasurface neural processing unit (NPU) to execute machine readable code instructions of a conditional generative adversarial network (cGAN) algorithm that receives, as input, the feature characteristics data of the captured incident radiofrequency signal, the captured incident radiofrequency signal, and a generated random noise signal from a noise generator to generate, as output, a filtered offset radiofrequency signal; and
the metasurface hardware controller to transmit the filtered offset radiofrequency signal to metasurface embedded microcontrollers to apply an appropriate attenuation and phase change at the metasurface unit cells and combine the filtered offset radiofrequency signal with the incident radiofrequency signal into the reflected radiofrequency signal having a suppressed interference component reflected off of the reconfigurable metasurface unit cell array.

2. The reconfigurable metasurface unit cell array of claim 1, wherein the feature characteristics data of the captured incident radiofrequency signal further includes angle-of-arrival (AoA) data, angle-of-departure (AoD) data, and time-of-flight (ToF) data.

3. The reconfigurable metasurface unit cell array of claim 1 further comprising:
the centralized metasurface hardware controller to execute machine readable code instructions of a Fourier transform algorithm to convert time-domain signals of the captured incident radiofrequency signal into frequency-domain signal data to separate the captured incident radiofrequency signal into the wireless communication component and an interference component indicating an ongoing consistent interference component prior to input into the cGAN algorithm at the hardware metasurface NPU.

4. The reconfigurable metasurface unit cell array of claim 1 further comprising:
the centralized metasurface hardware controller to execute machine readable code instructions of a wavelet transform algorithm at the signal feature extraction and preprocessing module to separate the captured incident radiofrequency signal into the wireless communication component and the interference component indicating the transient interference component with varying frequency and time resolution prior to input into the cGAN algorithm at the hardware metasurface NPU.

5. The reconfigurable metasurface unit cell array of claim 1, wherein:
a first subset of the plurality of metasurface unit cells are formed into a first metasurface unit cell subgroup of the reconfigurable metasurface unit cell array, wherein the first metasurface unit cell subgroup is operatively coupled to a first metasurface embedded microcontroller of a plurality of the metasurface embedded microcontrollers; and
the first metasurface unit cell subgroup is one of a plurality of metasurface unit cell subgroups formed within the reconfigurable metasurface unit cell array.

6. The information handling system of claim 1 further comprising:
an attenuator circuit operatively coupled to each of the plurality of metasurface embedded microcontrollers that is addressable by each of the plurality of metasurface embedded microcontrollers to derive the appropriate attenuation change to filtered offset radiofrequency signal applied in the reflected radiofrequency signal reflected off of the surface of the reconfigurable metasurface unit cell array for signal gain or interference suppression.

7. The reconfigurable metasurface unit cell array of claim 1 further comprising:
a tunable delay circuit operatively coupled to each of the plurality of metasurface embedded microcontrollers that is addressable by each of the plurality of metasurface embedded microcontrollers to derive the appropriate phase changes to the filtered offset radiofrequency signal applied across the plurality of metasurface unit cells to the reflected radiofrequency signal reflected off of the surface of the reconfigurable metasurface unit cell array for amplitude gain, beamforming directionality, and interference suppression.

8. The reconfigurable metasurface unit cell array of claim 1 further comprising:
the centralized metasurface hardware controller to execute machine readable code instructions of a deep reinforcement learning (DRL) algorithm to manage instructions to the plurality of metasurface embedded microcontrollers to direct control of phase shift changes and amplitude adjustment to the filtered offset radiofrequency signal applied across the plurality of metasurface unit cells for efficient allocation of resources and timely changes in the reflected radiofrequency signal from the surface of the reconfigurable metasurface unit cell array with beamforming directionality, amplitude gain, and interference suppression.

9. A method of mitigating radiofrequency signal interference in a radiofrequency environment at a reconfigurable metasurface unit cell array, comprising:
receiving an incident radiofrequency signal from the radiofrequency environment at a surface of the reconfigurable metasurface unit cell array to extend reach of the incident radiofrequency signal in a reflected radiofrequency signal, wherein the reconfigurable metasurface unit cell array comprises a plurality of reconfigurable unit cells formed into a plurality of metasurface unit cell subgroups, wherein each metasurface unit cell subgroup is operatively coupled to a metasurface embedded microcontroller;
coupling, via a partial signal coupler, a portion of the incident radiofrequency signal into a radiofrequency/electromagnetic (RF/EM) circuit network below resonating antennas of each metasurface unit cell to transmit a captured incident radiofrequency signal to the metasurface embedded microcontroller of each metasurface unit cell subgroup which transmits the captured incident radiofrequency signal to the centralized metasurface hardware controller;
executing, via the centralized metasurface hardware controller, machine readable code instructions of a signal feature extraction and preprocessing module to identify feature characteristics data, including identifying a wireless communication component and interference components of the captured incident radiofrequency signal;
executing machine readable code instructions of a conditional generative adversarial network (cGAN) algorithm that receives, as input, the feature characteristics data of the captured incident radiofrequency signal, the captured incident radiofrequency signal, and a generated random noise signal from a noise generator to generate, as output, a filtered offset radiofrequency signal; and
transmitting the filtered offset radiofrequency signal to metasurface embedded microcontrollers to apply an appropriate attenuation and phase change at the metasurface unit cells and combine the filtered offset radiofrequency signal with the incident radiofrequency signal into the reflected radiofrequency signal having a suppressed interference component reflected off of the reconfigurable metasurface unit cell array.

10. The method of claim 9, wherein the feature characteristics data of the captured incident radiofrequency signal include angle-of-arrival (AoA) data, angle-of-departure (AoD) data, and time-of-flight (ToF) data.

11. The method of claim 9 further comprising:
executing, via the centralized metasurface hardware controller, machine readable code instructions of a Fourier transform algorithm to convert time-domain signals of the captured incident radiofrequency signal into frequency-domain signal data to separate the captured incident radiofrequency signal into the wireless communication component and an interference component indicating an ongoing consistent interference component prior to input into the cGAN algorithm at the hardware metasurface NPU.

12. The method of claim 9 further comprising:
executing, via centralized metasurface hardware controller, machine readable code instructions of a wavelet transform algorithm at the signal feature extraction and preprocessing module to separate the captured incident radiofrequency signal into the wireless communication component and the interference component indicating the transient interference component with varying frequency and time resolution prior to input into the cGAN algorithm at the hardware metasurface NPU.

13. The method of claim 9 further comprising:
adjusting a tunable delay circuit operatively coupled to each of the plurality of metasurface embedded microcontrollers as directed by the centralized metasurface hardware controller to derive the appropriate phase changes to the filtered offset radiofrequency signal applied across the plurality of metasurface unit cell subgroups to the reflected radiofrequency signal reflected off of the surface of the reconfigurable metasurface unit cell array for amplitude gain, beamforming directionality and interference suppression.

14. A reconfigurable metasurface unit cell array comprising:
a centralized metasurface hardware controller, a metasurface memory device, and a metasurface power management unit (PMU) to provide power to the centralized metasurface hardware controller and metasurface memory device;
the reconfigurable metasurface unit cell array comprising a plurality of reconfigurable unit cells formed into a plurality of metasurface unit cell subgroups, wherein each metasurface unit cell subgroup is operatively coupled to a metasurface embedded microcontroller; and
the first metasurface unit cell subgroup is one of a plurality of metasurface unit cell subgroups formed within the reconfigurable metasurface unit cell array. to reflect a reflected radiofrequency signal from an incident radiofrequency signal from a radiofrequency environment at the surface of the reconfigurable metasurface unit cell array;
the plurality of metasurface unit cells coupling, via a partial signal coupler, a portion of the incident radiofrequency signal into a radiofrequency/electromagnetic (RF/EM) circuit network below resonating antennas of each metasurface unit cell to transmit a captured incident radiofrequency signal to the metasurface embedded microcontroller of each metasurface unit cell subgroup which transmits the captured incident radiofrequency signal to the centralized metasurface hardware controller;
the centralized metasurface hardware controller to execute machine readable code instructions of a signal feature extraction and preprocessing module to identify feature characteristics data, including identifying a wireless communication component and interference components of the captured incident radiofrequency signal;
a hardware metasurface neural processing unit (NPU) to execute machine readable code instructions of a conditional generative adversarial network (cGAN) algorithm that receives, as input, the feature characteristics data of the captured incident radiofrequency signal, the captured incident radiofrequency signal, and a generated random noise signal from a noise generator to generate, as output, a filtered offset radiofrequency signal; and
the metasurface hardware controller to transmit the filtered offset radiofrequency signal to metasurface embedded microcontrollers to apply an appropriate attenuation and phase change at the metasurface unit cells and combine the filtered offset radiofrequency signal with the incident radiofrequency signal into the reflected radiofrequency signal having a suppressed interference component reflected off of the reconfigurable metasurface unit cell array.

15. The reconfigurable metasurface unit cell array of claim 14, wherein the feature characteristics data of the captured incident radiofrequency signal further includes angle-of-arrival (AoA) data, angle-of-departure (AoD) data, and time-of-flight (ToF) data.

16. The reconfigurable metasurface unit cell array of claim 14 further comprising:
the metasurface hardware controller to execute machine readable code instructions of a Fourier transform algorithm to convert time-domain signals of the captured incident radiofrequency signal into frequency-domain signal data to separate the captured incident radiofrequency signal into the wireless communication component and an interference component indicating an ongoing consistent interference component prior to input into the cGAN algorithm at the hardware metasurface NPU.

17. The reconfigurable metasurface unit cell array of claim 14 further comprising:
the centralized metasurface hardware controller to execute machine readable code instructions of a wavelet transform algorithm at the signal feature extraction and preprocessing module to separate the captured incident radiofrequency signal into the wireless communication component and the interference component indicating the transient interference component with varying frequency and time resolution prior to input into the cGAN algorithm at the hardware metasurface NPU.

18. The information handling system of claim 14 further comprising:
an attenuator circuit operatively coupled to each of the plurality of metasurface embedded microcontrollers that is addressable by each of the plurality of metasurface embedded microcontrollers to derive the appropriate attenuation change to filtered offset radiofrequency signal applied in the reflected radiofrequency signal reflected off of the surface of each metasurface unit cell subgroup for signal gain and interference suppression.

19. The reconfigurable metasurface unit cell array of claim 14 further comprising:
a tunable delay circuit operatively coupled to each of the plurality of metasurface embedded microcontrollers that is addressable by each of the plurality of metasurface embedded microcontrollers to derive the appropriate phase changes to the filtered offset radiofrequency signal applied across the plurality of metasurface unit cell subgroups to the reflected radiofrequency signal reflected off of the surface of the reconfigurable metasurface unit cell array for amplitude gain, beamforming directionality, and interference suppression.

20. The reconfigurable metasurface unit cell array of claim 14 further comprising:
the centralized metasurface hardware controller to execute machine readable code instructions of a deep reinforcement learning (DRL) algorithm to manage instructions to the plurality of metasurface embedded microcontrollers to direct control of phase shift changes and amplitude adjustment to the filtered offset radiofrequency signal applied across the plurality of metasurface unit cell subgroups for efficient allocation of resources and timely changes in the reflected radiofrequency signals from the surface of the reconfigurable metasurface unit cell array with beamforming directionality, amplitude gain, and interference suppression.
